(19) United States
(12) Patent Application Publication
(10) Pub. No.: US 2026/0189043 A1
(43) Pub. Date: Jul. 2, 2026

(54) ELECTRIC CIRCUIT, BATTERY MANAGEMENT SYSTEM, AND ELECTRIC VEHICLE

(71) Applicant: EVE ENERGY CO., LTD., Huizhou (CN)

(72) Inventors: Zhen LIU, Huizhou (CN); Wenbing XIAO, Huizhou (CN); Shaowei XIE, Huizhou (CN); Liping WAN, Huizhou (CN)

(73) Assignee: EVE ENERGY CO., LTD., Huizhou (CN)

(21) Appl. No.: 19/549,017

(22) Filed: Feb. 25, 2026

Related U.S. Application Data
(63) Continuation-in-part of application No. PCT/CN2024/114558, filed on Aug. 26, 2024.

(30) Foreign Application Priority Data
Aug. 25, 2023 (CN) 202311084408.7
Aug. 25, 2023 (CN) 202311087750.2
Aug. 25, 2023 (CN) 202322305685.8
Aug. 25, 2023 (CN) 202322305751.1
Aug. 25, 2023 (CN) 202322305827.0

(51) Int. Cl. H02J 7/82; G01R 31/327; G01R 31/382; H02J 7/00; H02J 7/96

(52) U.S. Cl. CPC H02J 7/82; G01R 31/3277; G01R 31/382; H02J 7/865; H02J 7/96

(57) ABSTRACT

This application presents a circuit, a battery management system, and an electric vehicle. The circuit includes: a first current collection module, a second current collection module and a calculation module. The first current collection module and the second current collection module are respectively connected in series with a main circuit and a control circuit of the battery management system. The calculation module calculates a state of charge (SOC) value of the battery management system based on the first current information collected by the first current collection module and the second current information collected by the second current collection module.

This application is a continuation application of International Application No. PCT/CN2024/114558, filed on Aug. 26, 2024, which claims priority to and the benefit of Chinese Patent Applications No. 202322305685.8, 202322305751.1, 202311084408.7, 202322305827.0, and 202311087750.2, filed with CNIPA on Aug. 25, 2023. The entire disclosures of the above applications are incorporated herein by reference.

### TECHNICAL FIELD

The application relates to the field of battery technology, and in particular to an electric circuit, a battery management system and an electric vehicle.

### BACKGROUND

State of Charge (SOC) refers to remaining energy in a battery, and SOC measurement accuracy is an important indicator of a battery management system. The SOC measurement of the battery management system applies an ampere-hour integral method to calculate accumulated quantity of electric charge, and has been widely used in power batteries and energy storage batteries.

### SUMMARY

In a first aspect, the present disclosure provides a SOC detection circuit of a battery management system, including:
a first current collection module, connected in series to a main circuit of the battery management system, and configured to collect first current information of the main circuit;
a second current collection module, connected in series to a control circuit of the battery management system and configured to collect second current information of the control circuit;
and
a calculation module, connected to the first current collection module and to the second current collection module, respectively, and configured to calculate a SOC value of the battery management system based on the first current information and the second current information.

In a second aspect, the present disclosure provides charging and discharging control circuit, including:
a calculation module, configured to generate a first control signal and a second control signal in response to operation instructions from a target user;
a charging control module, connected to the calculation module and configured to generate a charging control voltage in response to the first control signal; and
a discharging control module, connected to the calculation module and configured to generate a discharging control voltage in response to the second control signal;
wherein the charging control voltage is configured to control a charging switch tube to turn on or turn off, and the discharging control voltage is configured to control a discharging switch tube to turn on or turn off.

In a third aspect, the present disclosure further provides boost control circuit, including:
a calculation module, configured to generate a first control signal and a second control signal in response to operation instructions from a target user;
a drive module, connected to the calculation module and a first power terminal, and configured to generate a switch control signal and a first voltage driving signal in response to the first control signal and the second control signal;
a switch module, connected to a second power terminal and the drive module, and configured to turn on or turn off in response to the switch control signal; and
a boost module, connected to the switch module and the drive module, and configured to receive a second power signal from the second power terminal when the switch module is turned on, and performs voltage boost according to the second power signal and the first voltage driving signal to output a second voltage signal;
wherein an amplitude of the second voltage signal is greater than an amplitude of the second power signal.

In a fourth aspect, the present disclosure further provides a switch tube detection circuit for a battery management system. The battery management system includes a battery, a charge switch module, a discharging switch module, and a charging and discharging interface. The charging and discharging interface is connected to the charging switch module at a first detection terminal, the charging switch module is connected to the discharging switch module at a second detection terminal, and the discharging switch module is connected to the battery at a third detection terminal.

The switch tube detection circuit of the battery management system comprising:
a calculation module, configured to generate a first control signal and a second control signal;
a first collection module, connected to the calculation module and the second detection terminal, and configured to collect a second voltage signal of the second detection terminal according to the first control signal;
a second collection module, connected to the calculation module, the first detection terminal, and the third detection terminal, and configured to collect a first voltage signal of the first detection terminal and a third voltage signal of the third detection terminal according to the second control signal;
wherein the calculation module is further configured to determine a fault state of the charging switch module and a fault state of the discharging switch module based on the first voltage signal, the second voltage signal, and the third voltage signal.

In a fifth aspect, the present disclosure further provides a battery management system, including:
a main circuit;
a control circuit; and
the SOC detection circuit for a battery management system according to the first aspect;
wherein the SOC detection circuit of the battery management system is connected to the main circuit and to the control circuit, respectively, and is configured to detect a total SOC value of the main circuit and control circuit.

In a sixth aspect, the present disclosure further provides a battery management system, including: the charging and discharging control circuit in the second aspect, the boost control circuit in the third aspect, or the switch tube detection circuit for the battery management system in the fourth aspect.

In a seventh aspect, the present disclosure further provides an electric vehicle, including: the SOC detection circuit for a battery management system in the first aspect, or the charging and discharging control circuit in the second aspect, or the boost control circuit in the third aspect, or the switch tube detection circuit for the battery management system in the fourth aspect, or the battery management system in the fifth aspect, or the battery management system in the sixth aspect.

### BRIEF DESCRIPTION OF THE DRAWINGS

FIG. 1 is a schematic structural diagram illustrating a connection between a battery management system and a state of charge (SOC) detection circuit of the battery management system provided by the present disclosure.

FIG. 2 is a schematic structural diagram illustrating a connection between another battery management system and an SOC detection circuit of the battery management system provided by the present disclosure.

FIG. 3 is a schematic structural diagram illustrating a connection between still another battery management system and an SOC detection circuit of the battery management system provided by the present disclosure.

FIG. 4 is a schematic structural diagram illustrating a connection between still another battery management system and an SOC detection circuit of the battery management system provided by the present disclosure.

FIG. 5 is a schematic structural diagram illustrating a connection between yet another battery management system and an SOC detection circuit of the battery management system provided by the present disclosure.

FIG. 6 is a schematic diagram of a circuit connection between a battery management system and an SOC detection circuit of the battery management system provided by the present disclosure.

FIG. 7 is a schematic structural diagram of a charging and discharging control circuit provided by the present disclosure.

FIG. 8 is a schematic structural diagram of another charging and discharging control circuit provided by the present disclosure.

FIG. 9 is a schematic structural diagram of an electric vehicle provided by the present disclosure.

FIG. 10 is a schematic structural diagram of a boost control circuit provided by the present disclosure.

FIG. 11 is a schematic structural diagram of another boost control circuit provided by the present disclosure.

FIG. 12 is a schematic structural diagram of another electric vehicle provided by the present disclosure.

FIG. 13 is a schematic structural diagram of a connection between a switch tube detection circuit of a battery management system and the battery management system provided by the present disclosure.

FIG. 14 is a schematic diagram of a circuit connection of the switch tube detection circuit of the battery management system and the battery provided by the present disclosure.

FIG. 15 is a schematic structural diagram of a connection between another switch tube detection circuit of the battery management system and the battery management system provided by the present disclosure.

FIG. 16 is a schematic diagram of a circuit connection between the another switch tube detection circuit of the battery management system and the battery provided by the present disclosure.

### DETAILED DESCRIPTION

In the description of the present disclosure, unless otherwise specified and limited, the terms “interconnect,” “connect,” and “fix” should be understood broadly. For example, these terms may indicate fixed connections, detachable connections, or integral connections; mechanical or electrical connections; direct connection, indirect connection through an intermediary, or internal communication of two elements or interaction relationship between two elements.

In the present disclosure, unless otherwise specified and limited, a first feature being “above” or “below” a second feature may include the first feature being in direct contact with the second feature, or the first feature being in contact with the second feature through other features therebetween instead of direct contact. Moreover, the first feature being “above,” “upper,” and “on” the second feature include the first feature being above and obliquely above the second feature, and the first feature being at a higher horizontal level than the second feature. The first feature being “below,” “under,” and “beneath” the second feature include the first feature being below and obliquely below the second feature, and the first feature being at a lower horizontal level than the second feature.

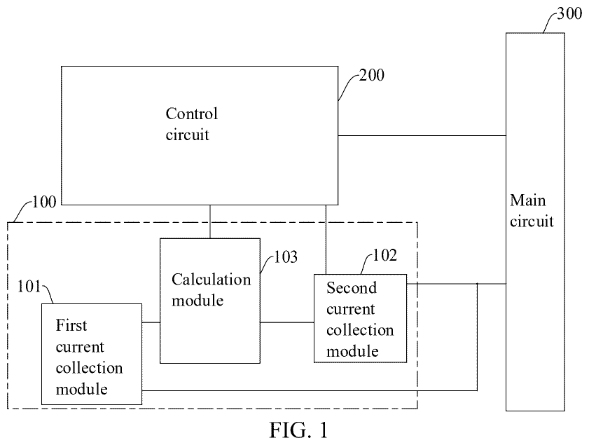

In the description of the following embodiments, the terms indicating orientation or positional relationship such as “upper,” “lower,” “left,” “right,” “front,” “rear,” and the like are based on the orientation or positional relationships shown in the drawings, for convenience of description and simplification of operation. These terms are not intended to indicate or imply that a referred device or element must have a specific orientation or must be constructed and operated in a specific orientation, and therefore should not be construed as limiting the present disclosure. In addition, the terms “first” and “second” are used for descriptive purposes only and do not imply any special meaning. Please refer to FIG. 1. FIG. 1 is a schematic structural diagram illustrating a connection between a battery management system and a state of charge (SOC) detection circuit of the battery management system provided by the present disclosure. As shown in FIG. 1, the battery management system includes a main circuit 300 and a control circuit 200. The main circuit 300 is controlled by the control circuit 200. The SOC detection circuit 100 of the battery management system includes: a first current collection module 101, a second current collection module 102, and a calculation module 103. The first current collection module 101 is connected in series to the main circuit 300, and the first current collection module 101 is configured to collect first current information of the main circuit 300. The second current collection module 102 is connected in series to the control circuit 200, and the second current collection module 102 is configured to collect second current information of the control circuit 200. The calculation module 103 is connected to the first current collection module 101 and the second current collection module 102, and the calculation module 103 is configured to calculate an SOC value of the battery management system based on the first current information and the second current information.

Specifically, the main circuit 300 of the battery management system is connected to a load or a charging power supply. When a battery 303 is being charged or discharging, the first current collection module 101 collects information of a current flowing through the main circuit 300 as the first current information.

For example, when the battery 303 is being charged, the first current information is a negative value; when the battery 303 is discharging, the first current information is a positive value. Since the control circuit 200 of the battery management system is configured to control the main circuit 300, the control circuit 200 itself also consumes electricity. Therefore, by arranging the second current collection module 102 connected in series to the control circuit 200 of the battery management system, the second current collection module 102 collects information of a current flowing through the control circuit 200 as the second current information.

Some examples of the calculation module 103 include, but are not limited to, microcontrollers (MCUs), central processing units (CPUs), graphics processing units (GPUs), various dedicated artificial intelligence (AI) computing chips, various computing units that run machine learning model algorithms, digital signal processors (DSPs), and any suitable processor, controller, and microcontroller, and the like.

The first current collection module 101 and the second current collection module 102 input the first current information and the second current information into the calculation module 103, respectively, and the calculation module 103 calculates the SOC of the battery management system according to a preset calculation rule. The first current collection module 101, the second current collection module 102, and the calculation module 103 together form the SOC detection circuit 100 of the battery management system, which concerns an impact of the self-consumed electricity of the control circuit 200 on the SOC calculation of the battery management system and hence reduces an error in the SOC calculation of the battery management system.

This technical solution of the present disclosure connects the first current collection module 101 in series to the main circuit 300 of the battery management system and thereby collects the first current information of the current flowing through the main circuit 300 by the first current collection module 101, and meanwhile connects the second current collection module 102 in series to the control circuit 200 of the battery management system and thereby collects the second current information of the current flowing through the control circuit 200 by the second current collection module 102. In this way, the self-consumed electricity of the control circuit 200 is taken into account. The SOC of the battery management system is calculated by the calculation module 103 based on the first current information and the second current information. The SOC detection circuit 100 of the battery management system is thus configured in this manner to calculate the self-consumed electricity of the control circuit 200 and the SOC value of the main circuit 300, thereby reducing an error in the SOC calculation of the battery management system made by the SOC detection circuit 100 of the battery management system. Therefore, the technical solution provided by the present disclosure here improves the accuracy of the SOC calculation of the battery management system, has a simple structure, and reduces cost.

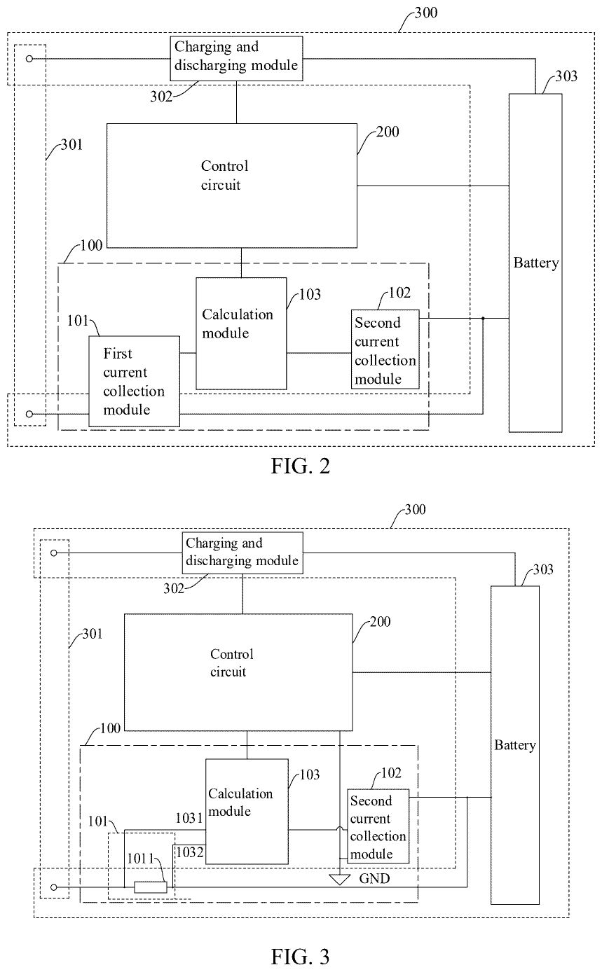

Please refer to FIG. 2. FIG. 2 is a schematic structural diagram illustrating a connection between another battery management system and the SOC detection circuit of the battery management system provided by the present disclosure. Based on various embodiments, optionally, the main circuit 300 of the battery management system includes a first interface 301, a charging and discharging control module 302, and a battery 303 that are connected in series. The first interface 301 is configured to connect to a load or a charging power supply.

The first current collection module 101 is connected between the first interface 301 and the battery 303, and is configured to collect a current flowing through the load of the main circuit 300.

Specifically, when the battery 303 is being charged, the first interface 301 is connected to the charging power supply, and the charging and discharging control module 302 controls the battery 303 to be charged. At this time, the first current collection module 101 collects a charging current flowing through the main circuit 300. When the battery 303 is discharging, the first interface 301 is connected to the load, and the charging and discharging control module 302 controls the battery 303 to discharge. At this time, the first current collection module 101 collects a discharging current of the main circuit 300 flowing through the load.

In this embodiment, by arranging the first current collection module 101 between the first interface 301 and the battery 303 of the main circuit 300, the current of the main circuit 300 can be collected during both the charging and the discharging of the battery 303 under the control of the charging and discharging control module 302. The collected first current information can be used to calculate the SOC value. This arrangement has a simple structure and is conducive to improving the accuracy of SOC calculation.

Please refer to FIG. 3. FIG. 3 is a schematic structural diagram illustrating a connection between still another battery management system and the SOC detection circuit of the battery management system provided by the present disclosure. Based on various embodiments, optionally, the first current collection module 101 includes a first sampling resistor 1011, a first terminal of the first sampling resistor 1011 is connected to the first interface 301 and to a first sampling terminal 1031 of the calculation module 103, a first pole of the battery 303 is connected to the charging and discharging module 302, and a second terminal of the first sampling resistor 1011 is connected to a second pole of the battery 303 and to a second sampling terminal 1032 of the calculation module 103.

Specifically, when the battery 303 is being charged, the first interface 301 is connected to the charging power supply, and the charging and discharging control module 302 controls the battery 303 to be charged. At this time, the first terminal of the first sampling resistor 1011 receives a charging current, collects information about the charging current, and inputs the collected current information into the first sampling terminal 1031 of the calculation module 103. The charging current flows from the second terminal of the first sampling resistor 1011 into the second pole of the battery 303. When the battery 303 is discharging, the first interface 301 is connected to the load, and the charging and discharging control module 302 controls the battery 303 to discharge. At this time, the second terminal of the first sampling resistor 1011 receives a discharging current, and the discharging current flows into the load from the first terminal of the first sampling resistor 1011. The first sampling resistor 1011 collects information about the discharging current and inputs the collected current information into the first sampling terminal 1031 of the calculation module 103.

In this embodiment, the first sampling resistor 1011 is arranged in the first current collection module 101, and the two terminals of the first sampling resistor 1011 are respectively connected to the first interface 301 and the second pole of the battery 303, so that when the battery 303 is being charged or is discharging, the current information of the main circuit 300 can be obtained by collecting a voltage across the first sampling resistor 1011 and using Ohm's law. The first sampling resistor 1011 is further connected to the calculation module 103, so that the collected first current information is input into the calculation module 103 to calculate the SOC value. This arrangement has a simple structure and is conducive to improving the accuracy of SOC calculation.

Referring to FIG. 3, on the basis of various embodiments, optionally, the control circuit 200 is connected to the battery 303 of the main circuit 300, and the battery 303 is configured to supply power to the control circuit 200. The second current collection module 102 is connected between a ground terminal GND of the control circuit 200 and the second pole of the battery 303, and is configured to collect a self-consumed current of the control circuit 200.

Specifically, the battery 303 of the main circuit 300 supplies power to the control circuit 200, and a supply current flows into the control circuit 200. After being consumed by the control circuit 200, the supply current flows through the ground terminal GND shared by all components in the control circuit 200 and through the second current collection module 102, and flows to the second pole of the battery 303. Thus, the second current collection module 102 may collect self-consumed current information of the control circuit 200.

In this embodiment, by arranging the second current collection module 102 between the ground terminal GND of the control circuit 200 and the second pole of the battery 303, the self-consumed current of the control circuit 200 can be collected, and the collected first current information can be used to calculate the SOC value. This arrangement has a simple structure and is conducive to improving the accuracy of SOC calculation.

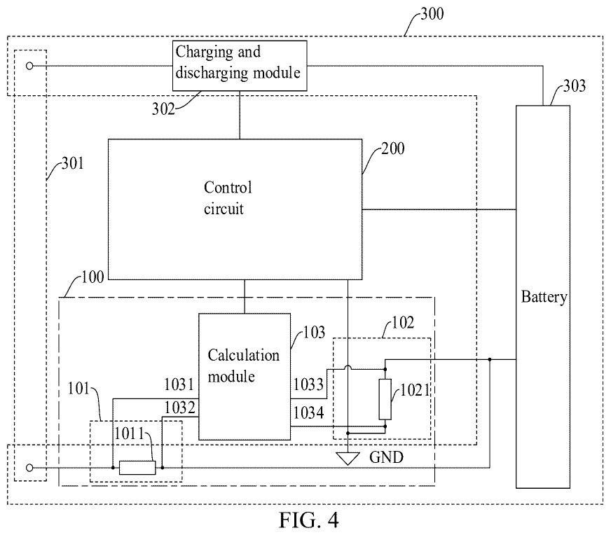

Please refer to FIG. 4. FIG. 4 is a schematic structural diagram illustrating a connection between still another battery management system and the SOC detection circuit of the battery management system provided by the present disclosure. Based on various embodiments, optionally, the second current collection module 102 includes a second sampling resistor 1021. A first terminal of the second sampling resistor 1021 is connected to the second pole of the battery 303 and to a third sampling terminal 1033 of the calculation module 103, and a second terminal of the second sampling resistor 1021 is connected to a fourth sampling terminal 1034 of the calculation module 103 and to the ground terminal GND.

Specifically, the self-consumed current of the control circuit 200 flows to the second terminal of the second sampling resistor 1021 and to the ground terminal GND shared by all the components in the control circuit 200. At this time, the second sampling resistor 1021 collects the current information and inputs it to the fourth sampling terminal 1034 of the calculation module 103. The self-consumed current of the control circuit 200 flows into the second pole of the battery 303 from the first terminal of the second sampling resistor 1021 after flowing through the second sampling resistor 1021. At this time, the second sampling resistor 1021 collects the current information and inputs it to the third sampling terminal 1033 of the calculation module 103.

In this embodiment, the second sampling resistor 1021 is arranged in the second current collection module 102, and the two terminals of the second sampling resistor 1021 are respectively connected to the ground terminal GND of the control circuit 200 and to the second pole of the battery 303. Consequently, a voltage across the second sampling resistor 1021 can be collected, thereby obtaining the self-consumed current information of the control circuit 200 by using Ohm's law. The second sampling resistor 1021 is further connected to the calculation module 103, so that the collected second current information is input into the calculation module 103 to calculate the SOC value. This arrangement has a simple structure and is conducive to improving the accuracy of SOC calculation.

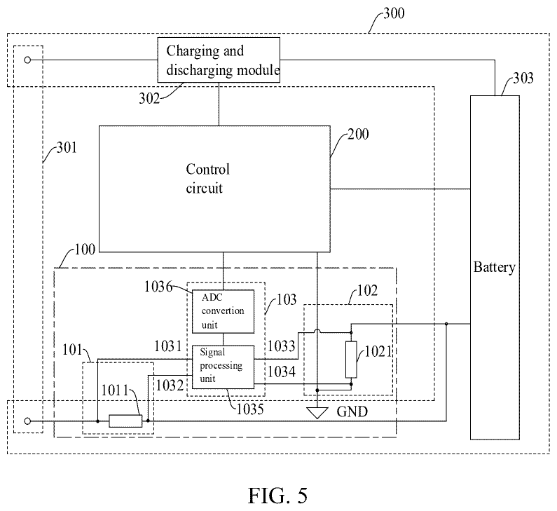

Please refer to FIG. 5. FIG. 5 is a schematic structural diagram illustrating a connection between yet another battery management system and the SOC detection circuit of the battery management system provided by the present disclosure. On the basis of various embodiments, optionally, the calculation module 103 includes an analog-to-digital conversion unit 1035 and a signal processing unit 1036.

The analog-to-digital conversion unit 1035 is connected to the first current collection module 101 and the second current collection module 102. The analog-to-digital conversion unit 1035 is configured to convert the first current information and the second current information into digital signals.

The signal processing unit 1036 is connected to the analog-to-digital conversion unit 1035 and is configured to calculate the SOC value of the battery management system based on the digital signals converted from the first current information and the second current information.

Specifically, since the first current information and the second current information respectively collected by the first current collection module 101 and the second current collection module 102 are analog signals and cannot be directly used for the calculation, the first current information and the second current information are converted into the digital signals by the analog-to-digital conversion unit 1035. The digital signals converted from the first current information and the second current information are input to the signal processing unit 1036, so that the signal processing unit 1036 may calculate the SOC value of the battery management system.

For example, the signal processing unit 1036 may implement a method of calculating an SOC value of a battery management system based on an ampere-hour integral method, and a principle of the method is: calculating a relative change in energy of the battery 303 by continuously integrating a current over a period of time and comparing the integrated current to a rated capacity of the battery 303, and using an initial SOC value to calculate a current SOC value. For example, its mathematical expression is:

$$SOC ( t ) \text{?} SOC ( t \text{?} ) - \frac{1}{CN} \int \text{?} \text{?} η \times 1 ( t ) dt , \qquad ( 1 )$$

$$\text{?} \text{indicates text missing or illegible when filed}$$

where SOC(t) represents the SOC value of the battery management system, SOC(t₀) represents the initial SOC value determined based on open-circuit voltage, CN represents the rated capacity of battery 303, η is a coulombic efficiency, I represents current information consumed by the battery system (which is current information of the main circuit 300 in existing technologies), and t represents time.

Since the current information consumed by the battery system includes current information (i.e., the first current information) flowing through the main circuit 300 and current information (i.e., the second current information) consumed by the control circuit 200. For example, the signal processing unit 1036 may calculate the SOC value of the battery management system according to the formula (1), where I is a sum of the first current information and the second current information. This calculation can be implemented through existing program algorithms. It should be noted that the SOC detection circuit of the battery management system provided by the present disclosure may be configured to execute other existing SOC calculation methods to calculate the SOC of the battery management system.

The Coulombic efficiency, that is, discharging efficiency, refers to a ratio of a discharging capacity of the battery 303 to a charging capacity during a same cycle, that is, a percentage ratio of the discharging capacity to the charging capacity.

In this embodiment, by arranging the analog-to-digital conversion unit 1035 and the signal processing unit 1036 in the calculation module 103, the first current information and the second current information are converted into digital signals to calculate the SOC value of the battery management system. This is conducive to making the SOC calculation of the battery management system more accurate.

The present disclosure further provides a battery management system, including the main circuit 300, the control circuit 200, and the SOC detection circuit 100 of the battery management system provided in any embodiment of the present disclosure.

The SOC detection circuit 100 of the battery management system is connected to the main circuit 300 and the control circuit 200. The SOC detection circuit 100 of the battery management system is configured to detect a total SOC value of the main circuit 300 and the control circuit 200.

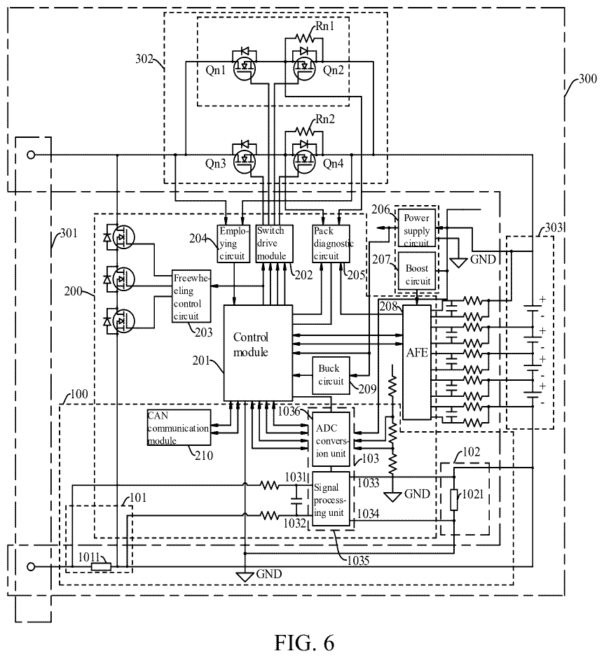

Please refer to FIG. 6. FIG. 6 is a schematic diagram of a circuit connection between the battery management system and the SOC detection circuit of the battery management system provided by the present disclosure. On the basis of various embodiments, optionally, the main circuit 300 includes a first interface 301, a charging and discharging control module 302, and a battery 303 that are connected in series. The first interface 301 is configured to connect to a load or a charging power supply.

The control circuit 200 includes a control module 201 and a switch drive module 202 connected to the control module 201. The switch drive module 202 is configured to generate a driving signal according to a control signal of the control module 201. The driving signal is configured to control the charging and discharging control module 302 to be turned on or off. The control module 201 is connected to a battery 303, and the battery 303 is configured to supply power to the control module 201.

Optionally, the control circuit 200 further includes: a freewheeling control circuit 203, an employing circuit 204, a Pack diagnostic circuit 205, a power supply circuit 206, a boost circuit 207, an analog front-end (AFE) 208, a buck circuit 209, and a controller area network (CAN) communication module 210. The charging and discharging control module 302 further includes a first switch Qn3, a second switch Qn1, a third switch Qn4, a fourth switch Qn2, a resistor Rn1, and a resistor Rn2.

Specifically, when the battery 303 is being charged, the first interface 301 is connected to a charging power supply, and the battery 303 supplies power to the control module 201. The control module 201 controls the switch drive module 202 to generate a driving signal, which controls a charging control module in the charging and discharging control module 302 to turn on, so as to control the battery 303 to be charged. In such cases, the first current collection module 101 collects a charging current flowing through the main circuit 300. When the battery 303 is discharging, the first interface 301 is connected to the load, and the battery 303 supplies power to the control module 201. The control module 201 controls the switch drive module 202 to generate a driving signal, which controls a discharging control module in the charging and discharging control module 302 to turn on, so as to control the battery 303 to discharge. In such cases, the first current collection module 101 collects a discharging current of the main circuit 300 flowing through the load.

This technical solution provided by the present disclosure can realize SOC calculation of the battery management system by arranging the control module 201 and the switch drive module 202 in the control circuit 200 of the battery management system to control the battery 303 to charge and discharge, and to cooperate with the SOC detection circuit 100 of the battery management system. The technical solutions provided by the present disclosure can improve the accuracy of the SOC calculation in the battery management system, and have a simple structure and save costs.

The present disclosure further provides an electric vehicle that includes the SOC detection circuit 100 of the battery management system provided in any embodiment or includes the battery management system provided in any embodiment.

The electric vehicle provided by the present disclosure has the SOC detection circuit of the battery management system or the battery management system provided by any embodiment of the present disclosure.

In related technology, in a Battery Management System (BMS) system of an 12V low-voltage lithium car battery, the main circuit requires switches to control the charging and the discharging of the battery. For simplicity of control, existing charging and discharging control switches generally use relays. However, compared with metal oxide semiconductor (MOS) tubes, the relay has a shorter switch life and a larger space size.

To this end, in some implementations, the present disclosure provides a charging and discharging control circuit.

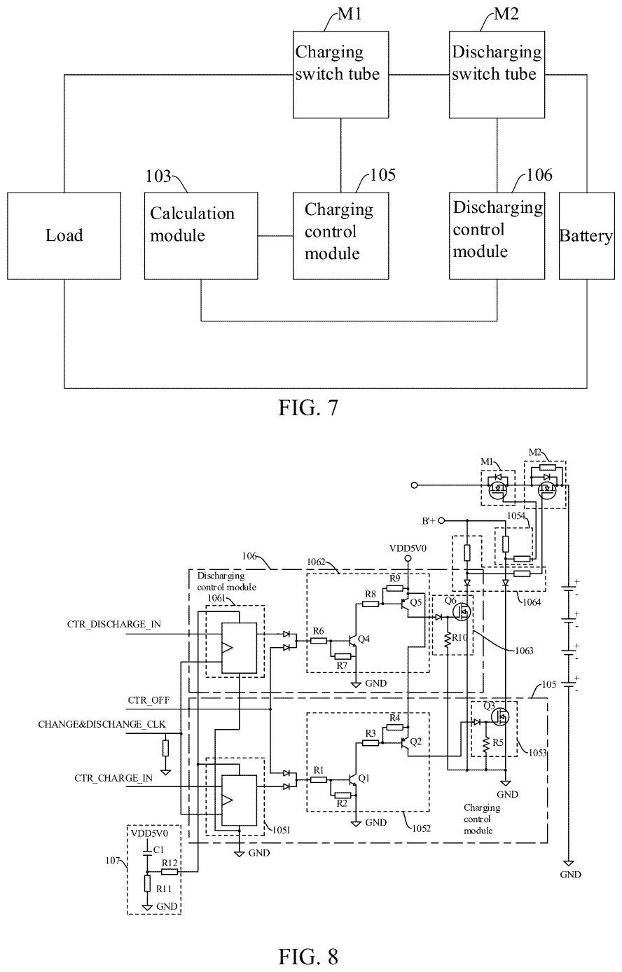

Please refer to FIG. 7. FIG. 7 is a schematic structural diagram of a charging and discharging control circuit provided by the present disclosure. As shown in FIG. 7, the charging and discharging control circuit provided in the present disclosure includes: a charging control module 105, a discharging control module 106, and a calculation module 103. The calculation module 103 is configured to generate a first control signal and a second control signal in response to operation instructions of a target user. The charging control module 105 is connected to the calculation module 103 and is configured to generate a charging control voltage in response to the first control signal. The discharging control module 106 is connected to the calculation module 103 and is configured to generate a discharging control voltage in response to the second control signal. The discharging control voltage is configured to control a charging switch tube M1 to turn on or turn off. The discharging control voltage is configured to control a discharging switch tube M2 to turn on or turn off.

Specifically, the calculation module 103 may be a microcontroller or other controllers capable of controlling or computing functions. The operation instructions of the target user may include plugging a charging gun into a charging pile and activating a charging button. Alternatively, the operation instructions that the target user sets may include electric vehicle startup.

The calculation module 103 may generate the first control signal and the second control signal according to the operation instructions of the target user. The first control signal may be a control signal that controls the charging control module 105 to turn on and output the charging control voltage. The charging control voltage is configured to control the charging switch tube M1 to turn on, so as to connect the power supply and the battery to be charged that are connected through the charging switch tube M1, enabling the power supply to charge the battery to be charged.

The second control signal may be a control signal that controls the discharging control module 106 to turn on and outputs the discharging control voltage. The discharging control voltage is configured to turn on the discharging switch tube M2, so as to connect a circuit where the battery and the load are connected through the discharging switch tube M2, enabling the battery to output electrical energy to the load.

The charging and discharging control circuit provided in the present disclosure generates the first control signal and the second control signal in response to the operation instructions of the target user by arranging the calculation module 103. Further, the charging control module 105 is configured to generate the charging control voltage in response to the first control signal, and the discharging control module 106 is configured to generate the discharging control voltage in response to the second control signal. The charging control voltage is configured to control the charging switch tube M1 to turn on or turn off, and the discharging control voltage is configured to control the discharging switch tube M2 to turn on or turn off. The charging and discharging control circuit provided in the present disclosure is configured to control the charging switch tube M1 and the discharging switch tube M2, which reduces a volume of the charging and discharging control circuit compared to a circuit that uses a relay for controlling the charging and the discharging. The charging and discharging control circuit provided by the present disclosure realizes independent control of the charging and the discharging, and avoids a large volume of the charging and discharging control circuit.

Please refer to FIG. 8. FIG. 8 is a schematic structural diagram of another charging and discharging control circuit provided by the present disclosure. Based on the embodiment, in combination with FIGS. 7 and 8, the charging control module 105 of the charging and discharging control circuit provided in the present disclosure may include: a first follower unit 1051, a first driving unit 1052, a first switching unit 1053, and a first output unit 1054. The first follower unit 1051 is connected to the calculation module 103, and the first follower unit 1051 is configured to receive the first control signal and output the first control signal. The first driving unit 1052 is connected to the first follower unit 1051, and the first driving unit 1052 is configured to turn on according to the first control signal and output a first power signal. The first switching unit 1053 is connected to the first driving unit 1052, and the first switching unit 1053 is configured to turn on according to the first power signal. The first output unit 1054 is connected to the first switching unit 1053, and the first output unit 1054 is configured to output the charging control voltage.

Specifically, the first follower unit 1051 may include: a voltage follower or a flip-flop. The first follower unit 1051 receives a first control signal, which includes a trigger signal CHANGE&DISCHANGE_CLK and a first control signal CTR_CHARGE_IN. The first follower unit 1051 outputs the received first control signal CTR_CHARGE_IN according to the received trigger signal CHANGE&DISCHANGE_CLK.

The first driving unit 1052 receives the first control signal CTR_CHARGE_IN output by the first follower unit 1051. The first driving unit 1052 is turned on and outputs the first power signal. The first power signal is output to a control terminal of the first switching unit 1053. The first switching unit 1053 is turned on according to the first power signal received by its control terminal. A first terminal of the first switching unit 1053 is connected to a second power input terminal B′+, and a second terminal of the first switching unit 1053 is connected to ground. The first output unit 1054 is connected between the second power input terminal B′+ and the first terminal of the first switching unit 1053. When the first switching unit 1053 is turned on, the first output unit 1054 performs voltage division on a second power signal and outputs a charging control voltage.

Optionally, based on various embodiments, referring to FIG. 8, the first driving unit 1052 includes: a first switch tube Q1, a second switch tube Q2, a first resistor R1, a second resistor R2, a third resistor R3, and a fourth resistor R4. A first terminal of the first resistor R1 is connected to an output terminal of the first follower unit 1051, a second terminal of the first resistor R1 is connected to a control terminal of the first switch tube Q1, a first electrode of the first switch tube Q1 is connected to a control terminal of the second switch tube Q2, and a second electrode of the first switch tube Q1 is connected to ground. A first electrode of the second switch tube Q2 is configured to be connected to a first power input terminal VDD5V0, and a second electrode of the second switch tube Q2 is connected to the control terminal of the first switching unit 1053. The second resistor R2 is connected between the control terminal and the second electrode of the first switch tube Q1, and the third resistor R3 is connected between the first electrode of the first switch tube Q1 and the control terminal of the second switch tube Q2. The fourth resistor R4 is connected between the control terminal of the second switch tube Q2 and the first electrode of the second switch tube Q2.

Specifically, when the first switch tube Q1 is configured to receives the first control signal as an input from its control terminal, the first switch tube Q1 conducts between the first and second electrodes through voltage-dividing protection of the first resistor R1 and the second resistor R2. The voltage of the first electrode of the first switch tube Q1 is at a low level. Since the control terminal of the second switch tube Q2 is connected to the first electrode of the first switch tube Q1 through the third resistor R3, the control terminal of the second switch tube Q2 receives the low level as an input. The second switch tube Q2 is configured to be turned on when the low level is inputted to its control terminal, so as to conduct between the second and first electrodes of the second switch tube Q2 and output the first power signal to the second electrode of the second switch tube Q2. The second electrode of the second switch tube Q2 serves as an output terminal of the first driving unit 1052. The third resistor R3 plays a current limiting protection role, and the fourth resistor R4 and the third resistor R3 play a voltage-division role.

Optionally, based on various embodiments, referring to FIG. 8, the first switching unit 1053 may include a third switch tube Q3 and a fifth resistor R5. A control terminal of the third switch tube Q3 is connected to the output terminal of the first driving unit 1052, a first electrode of the third switch tube Q3 is connected to the first terminal of the first output unit 1054, and a second electrode of the third switch tube Q3 is grounded. The fifth resistor R5 is connected between the control terminal and second electrode of the third switch tube Q3. Optionally, the first output unit 1054 includes a first voltage division network, a first terminal of the first voltage division network is connected to the first electrode of the third switch tube Q3, a second terminal of the first voltage division network is configured to be connected to the second power input terminal B′+, and a third terminal of the first voltage division network is configured to be connected to a control terminal of the charging switch tube M1.

Specifically, the control terminal of the third switch tube Q3 receives the first power signal output by the first driving unit 1052. Since the second electrode of the third switch tube Q3 is grounded, the first electrode of the third switch tube Q3 serves as the output terminal of the first switching unit 1053. When the third switch tube Q3 is conducting between the first and second electrodes based on the first power signal received by its control terminal, the first switch unit 1053 outputs a low level, and then the first voltage division network outputs a low level, which controls the charging switch tube M1 to turn off.

When the third switch tube Q3 is not conducting between the first and second electrodes based on the first power signal received by its control terminal, the first and second electrodes of the first switching unit 1053 outputs a high level, and then the first voltage division network outputs a high level, which controls the charging switch tube M1 to turn on.

Optionally, based on various embodiments, referring to FIG. 8, the discharging control module 106 includes: a second follower unit 1061, a second driving unit 1062, a second switching unit 1063, and a second output unit 1064. The second follower unit 1061 is connected to the calculation module 103 and is configured to receive the second control signal and output the second control signal. The second driving unit 1062 is connected to the second follower unit 1061 and is configured to turn on according to the second control signal and output the first power signal. The second switching unit 1063 is connected to the second driving unit 1062, and is configured to turn on according to the first power signal. The second output unit 1064 is connected to the second switching unit 1063 and is configured to output the discharging control voltage.

Specifically, the second follower unit 1061 may include: a voltage follower or a flip-flop. The second follower unit 1061 receives the second control signal, which includes a trigger signal CHANGE&DISCHANGE_CLK and a second control signal CTR_DISCHARGE_IN. The second follower unit 1061 outputs the received second control signal CTR_DISCHARGE_IN according to the received trigger signal CHANGE&DISCHANGE_CLK.

The second driving unit 1062 receives the second control signal CTR_DISCHARGE_IN output by the second follower unit 1061 and turns on, and outputs the first power signal. The first power signal is output to a control terminal of the second switching unit 1063. The second switching unit 1063 is turned on according to the first power signal received by its control terminal. A first terminal of the second switching unit 1063 is connected to the second power input terminal B′+, and a second terminal of the second switching unit 1063 is connected to ground. The second output unit 1064 is connected between the second power input terminal B′+ and the first terminal of the second switching unit 1063. When the second switching unit 1063 is turned on, the second output unit 1064 performs a voltage division on a second power signal of the second power input terminal B′+ and outputs the discharging control voltage.

Optionally, based on various embodiments, referring to FIG. 8, the second driving unit 1062 includes: a fourth switch tube Q4, a fifth switch tube Q5, a sixth resistor R6, a seventh resistor R7, an eighth resistor R8, and a ninth resistor R9. A first terminal of the sixth resistor R6 is connected to an output terminal of the second follower unit 1061, a second terminal of the sixth resistor R6 is connected to a control terminal of the fourth switch tube Q4. A first electrode of the fourth switch tube Q4 is connected to a control terminal of the fifth switch tube Q5. A first electrode of the fourth switch tube Q4 is connected to a control terminal of the fifth switch tube Q5, and a second electrode of the fourth switch tube Q4 is connected to ground. A first electrode of the fifth switch tube Q5 is configured to be connected to the first power input terminal VDD5V0, and a second electrode of the fifth switch tube Q5 is connected to the control terminal of the second switching unit 1063. The seventh resistor R7 is connected between the control terminal and the second electrode of the fourth switch tube Q4. The eighth resistor R8 is connected between the first electrode of the fourth switch tube Q4 and the control terminal of the fifth switch tube Q5. The ninth resistor R9 is connected between the control terminal of the fifth switch tube Q5 and the first electrode of the fifth switch tube Q5.

Specifically, when the fourth switch tube Q4 is configured to receives the second control signal as an input from its control terminal, the fourth switch tube Q4 is conducting between the first and second electrodes through voltage-dividing protection of the sixth resistor R6 and the seventh resistor R7. The voltage of the first electrode of the fourth switch tube Q4 is at a low level. The control terminal of the fifth switch tube Q5 is connected to the first electrode of the fourth switch tube Q4 through the eighth resistor R8. The control terminal of the fifth switch tube Q5 receives a low level as an input. The fifth switch tube Q5 is configured to be turned on when the low level is inputted to its control terminal, so as to conduct between the second electrode of the fifth switch tube Q5 and the first electrode of the fifth switch tube Q5, and output the first power signal to the second electrode of the fifth switch tube Q5. The second electrode of the fifth switch tube Q5 serves as an output terminal of the second driving unit 1062. The eighth resistor R8 plays a current limiting protection role, and the ninth resistor R9 and the eighth resistor R8 play a voltage-division role.

Optionally, based on various embodiments, referring to FIG. 8, the second switching unit 1063 includes: a sixth switch tube Q6 and a tenth resistor R10. A control terminal of the sixth switch tube Q6 is connected to the output terminal of the second driving unit 1062, a first electrode of the sixth switch tube Q6 is connected to a first terminal of the second output unit 1064, and a second electrode of the sixth switch tube Q6 is grounded. The tenth resistor R10 is connected between the control terminal and the second electrode of the sixth switch tube Q6.

Optionally, the second output unit 1064 includes: a second voltage division network. A first terminal of the second voltage division network is connected to the first electrode of the sixth switch tube Q6, a second terminal of the second voltage division network is configured to be connected to the second power input terminal B′+, and a third terminal of the second voltage division network is configured to be connected to the control terminal of the discharging switch tube M2.

Specifically, the control terminal of the sixth switch tube Q6 receives the first power signal output by the second driving unit 1062. Since the second electrode of the sixth switch tube Q6 is grounded, the first electrode of the sixth switch tube Q6 serves as the output terminal of the second switching unit 1063. When the sixth switch tube Q6 is turned on based on the first power signal received by its control terminal, the sixth switch tube Q6 is conducting between the first and second electrodes, the output terminal of the second switching unit 1063 outputs a low level, and the second voltage division network outputs a low level, which controls the discharging switch tube M2 to turn off.

When the sixth switch tube Q6 is turned off based on the first power signal received by its control terminal, the sixth switch tube Q6 is not conducting between the first and second electrodes, the output terminal of the second switching unit 1063 outputs a high level, and the second voltage division network outputs a high level, which controls the discharging switch tube M2 to turn on.

It should be noted that, when the third switch tube Q3 is turned off, the sixth switch tube Q6 is turned on, therefore, the discharging switch tube M2 is turned off, and the charging switch tube M1 is turned on, thus charging the battery. When the sixth switch tube Q6 is turned off, the third switch tube Q3 is turned on, so that the discharging switch tube M2 is turned on, and the charging switch tube M1 is turned off, so that the battery supplies power to the load.

Optionally, based on various embodiments, referring to FIG. 8, the charging and discharging control circuit provided by the present disclosure may further include: an initialization module 107. An input terminal of the initialization module 107 is configured to be connected to the first power input VDD5V0, and an output terminal of the initialization module 107 is connected to the charging control module 105 and the discharging control module 106. The initialization module 107 is configured to initialize the charging control module 105 and the discharging control module 106 in an initial stage, and control the charging switch tube M1 and the discharging switch tube M2 to turn off.

Specifically, in the initial state when the power supply starts, that is, the initial stage, the initialization module 107 initializes the charging control module 105 and the discharging control module 106, controls all of the first switch tube Q1 to the sixth switch tube Q6 to turn on, so that the charging switch tube M1 is turned off, and the discharging switch tube M2 is turned off. The charging and discharging control circuit is initialized to ensure its safety and reliability.

Optionally, based on various embodiments, referring to FIG. 8, the initialization module 107 includes: a first capacitor C1, an eleventh resistor R11, and a twelfth resistor R12. A first terminal of the first capacitor C1 is configured to be connected to the first power input terminal VDD5V0, a second terminal of the first capacitor C1 is connected to a first terminal of the eleventh resistor R11 and a first terminal of the twelfth resistor R12, a second terminal of the eleventh resistor R11 is grounded, and a second terminal of the twelfth resistor R12 is connected to a reset terminal of the first follower unit 1051 of the charging control module 105 and to a reset terminal of the second follower unit 1061 of the discharging control module 106.

Specifically, in the initial stage, a voltage across the eleventh resistor R11 is at a high level. The eleventh resistor R11 and the first capacitor C1 form a charging and discharging time constant. An initialization signal is output through the twelfth resistor R12. The reset terminals of the initialized first follower unit 1051 and the second follower unit 1061 are configured as follows: SET=1, Reset=0, and Q=1.

Optionally, the initialization module 107 may further include: a protection control terminal CTR_OFF, which is connected to the calculation module 103. When the protection control terminal CTR_OFF receives a high-level signal, the charging switch tube M1 is turned off and the discharging switch tube M2 is controlled to be turned off, so that cells of the battery can be protected.

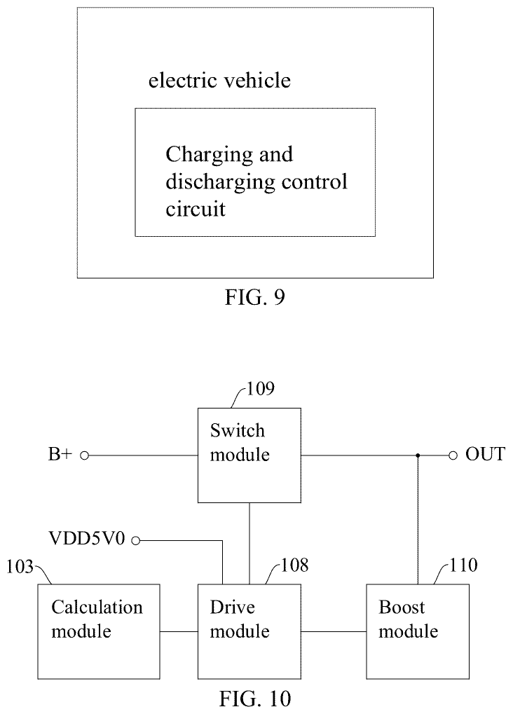

Please refer to FIG. 9. FIG. 9 is a schematic structural diagram of an electric vehicle provided by the present disclosure. As shown in FIG. 9, the battery vehicle provided in the present disclosure includes the charging and discharging control circuit proposed in the present disclosure.

In related technology, switches are required to charge and discharge the battery and protect the battery in the main circuit of the BMS system of the 12V low-voltage lithium car battery BMS system. When the switch uses an MOS tube to control the charging and discharging of the main circuit, a control voltage required by the MOS tube is high, resulting in insufficient driving voltage and low driving voltage stability of the MOS tube that controls the charging and discharging of a vehicle battery.

To this end, in some implementations, the present disclosure provides a boost control circuit.

Please refer to FIG. 10. FIG. 10 is a schematic structural diagram of a boost control circuit provided by the present disclosure. As shown in FIG. 10, the boost control circuit provided by the present disclosure includes: a switch module 109, a drive module 108, a boost module 110, and a calculation module 103. The calculation module 103 is configured to generate a first control signal CTR_CHARGE_A and a second control signal CTR_DISCHARGE_A in response to operation instructions of a target user. The drive module 108 is connected to the calculation module 103 and the first power terminal VDD5V0, and the drive module 108 is configured to generate a switch control signal and a first voltage driving signal in response to the first control signal CTR_CHARGE_A and the second control signal CTR_DISCHARGE_A. The switch module 109 is connected to the second power terminal B+ and the drive module 108, and the switch module 109 is configured to turn on or off in response to the switch control signal. The boost module 110 is connected to the switch module 109 and the drive module 108, and the boost module 110 is configured to receive the second power signal from the second power terminal B+ when the switch module 109 is turned on, and perform voltage boost according to the second power signal and the first voltage driving signal to output a second voltage signal. An amplitude of the second voltage signal is greater than an amplitude of the second power signal.

Specifically, the calculation module 103 generates the first control signal CTR_CHARGE_A and the second control signal CTR_DISCHARGE_A. The drive module 108 generates the switch control signal based on the first control signal CTR_CHARGE_A and the second control signal CTR_DISCHARGE_A. The switch control signal acts on a control terminal of the switch module 109 to turn on the switch module 109. After the switch module 109 is turned on, the switch module 109 allows the second power signal transmitted by the second power terminal B+ to be transmitted from a first terminal of the switch module 109 to a second terminal of the switch module 109.

The drive module 108 generates the first voltage driving signal based on the first power signal transmitted by the first power terminal VDD5V0 according to the first control signal CTR_CHARGE_A and the second control signal CTR_DISCHARGE_A. The first voltage driving signal is output to the boost module 110. The boost module 110 is connected between an output terminal of the switch module 109 and an output terminal of the drive module 108. The boost module 110 boosts a voltage at the output terminal of the switch module 109 according to the first voltage driving signal and the second power signal, and outputs the second voltage signal. The second terminal of the switch module 109 is connected to an output interface of the boost control circuit, and the second voltage signal output by the boost module 110 is relatively stable. Since the amplitude of the second voltage signal is higher than the amplitude of the second power signal, the second voltage signal output by the output interface can meet the requirements of the driving voltage of the MOS tube that controls the charging and discharging of the battery.

This technical solution provided in the present disclosure includes: generating the first control signal CTR_CHARGE_A and the second control signal CTR_DISCHARGE_A through the calculation module 103 in response to the operation instructions of the target user, and generating the switch control signal and the first voltage driving signal through the drive module 108 in response to the first control signal CTR_CHARGE_A and the second control signal CTR_DISCHARGE_A. By connecting the switch module 109 with the second power terminal B+ and the drive module 108, the switch module 109 may be turned on or off in response to the switch control signal. When the switch module 109 is turned on, the boost module 110 receives the second power signal and boosts it according to the first voltage driving signal and the second power signal, and outputs a second voltage signal with an amplitude greater than the second power signal. In this way, the second voltage signal output from the output interface of the boost control circuit can meet the requirements of the driving voltage of the MOS tube that controls the charging and discharging of the battery.

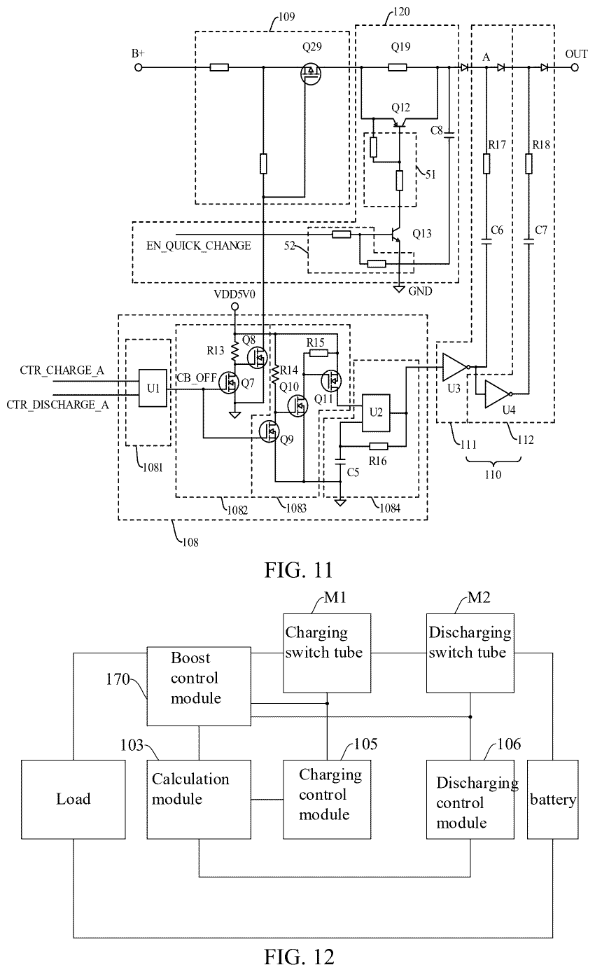

Please refer to FIG. 11. FIG. 11 is a schematic structural diagram of another boost control circuit provided by the present disclosure. Based on the embodiment, in combination with FIGS. 10 and 11, the drive module 108 may include: an input logic module 1081, a first drive module 1082, a second drive module 1083, and an output logic module 1084. The input logic module 1081 is connected to the calculation module 103, and the input logic module 1081 is configured to generate a first logic control signal according to the first control signal CTR_CHARGE_A and the second control signal CTR_DISCHARGE_A. The first drive module 1082 is connected to the input logic module 1081 and the switch module 109, and the first drive module 1082 is configured to turn on according to the first logic control signal and output the switch control signal to the switch module 109. The second drive module 1083 is connected to the input logic module 1081 and the first power terminal VDD5V0, and the second drive module 1083 is configured to output the first driving signal according to the first logic control signal and the voltage of the first power terminal VDD5V0. The output logic module 1084 is connected to the second drive module 1083, and the output logic module 1084 is configured to generate the first voltage driving signal according to the first driving signal.

Specifically, an input terminal of the input logic module 1081 is configured to receive the first control signal CTR_CHARGE_A and the second control signal CTR_DISCHARGE_A generated by the calculation module 103 as an input. The input logic module 1081 generates the first logic control signal based on the levels of the first control signal CTR_CHARGE_A and the second control signal CTR_DISCHARGE_A inputted to its input terminal. The first logic control signal is input to the first drive module 1082 and to the second drive module 1083, respectively. The first drive module 1082 generates the switch control signal based on the received first logic control signal. The control terminal of the switch module 109 is turned on according to the input switch control signal, and transmits the second power signal to the output terminal of the switch module 109.

The second drive module 1083 generates the first driving signal based on the received first logic control signal. The output logic module 1084 generates the first voltage driving signal based on the first driving signal input and a reference voltage input into the input terminals of the output logic module 1084. The first voltage driving signal is output to the boost module 110.

Optionally, based on various embodiments, in combination with FIGS. 10 and 11, the first drive module 1082 may include: a seventh switch tube Q7, an eighth switch tube Q8, and a thirteenth resistor R13. A control terminal of the seventh switch tube Q7 is connected to the output terminal of the input logic module 1081, a first electrode of the seventh switch tube Q7 is connected to a control terminal of the eighth switch tube Q8 and a first terminal of the thirteenth resistor R13, a second terminal of the thirteenth resistor R13 is configured to be connected to the first power terminal VDD5V0, a first electrode of the eighth switch tube Q8 is connected to the control terminal of the switch module 109, and a second electrode of the seventh switch tube Q7 and a second electrode of the eighth switch tube Q8 are connected to ground.

Specifically, when the seventh switch tube Q7 is turned off according to the first logic control signal inputted to its control terminal, the control terminal of the eighth switch tube Q8 receives the first power signal, for example, a high-level signal, and the eighth switch tube Q8 is turned on. When the eighth switch tube Q8 is turned on, an output terminal of the first drive module 1082 outputs the switch control signal, such as a low-level signal. The thirteenth resistor R13 plays a current limiting role.

Optionally, based on various embodiments, in combination with FIGS. 10 and 11, the second drive module 1083 may include: a ninth switch tube Q9, a tenth switch tube Q10, an eleventh switch tube Q11, a fourteenth resistor R14, and a fifteenth resistor R15. A control terminal of the ninth switch tube Q9 is connected to the output terminal of the input logic module 1081, and a first electrode of the ninth switch tube Q9 is connected to a control terminal of the tenth switch tube Q10 and a first terminal of the fourteenth resistor R14. A second terminal of the fourteenth resistor R14 is configured to be connected to the first power terminal VDD5V0. A first electrode of the tenth switch tube Q10 is connected to a control terminal of the eleventh switch tube Q11 and a first terminal of the fifteenth resistor R15. A second terminal of the fifteenth resistor R15 is connected to a first electrode of the eleventh switch tube Q11 and the first power terminal VDD5V0. A second electrode of the ninth switch tube Q9 and a second electrode of the tenth switch tube Q10 are grounded. A second electrode of the eleventh switch tube Q11 is connected to the output logic module 1084 as the output terminal of the second drive module 1083.

Specifically, the ninth switch tube Q9 is turned off based on the first logic control signal inputted into its control terminal, such as a low-level signal. When the ninth switch tube Q9 is turned off according to the first logic control signal inputted into its control terminal, the first power signal (for example, a high-level signal) is inputted into the control terminal of the tenth switch tube Q10, and the tenth switch tube Q10 is turned on. When the tenth switch tube Q10 is turned on, a low-level signal is inputted into the control terminal of the eleventh switch tube Q11, so that the eleventh switch tube Q11 is turned on. When the eleventh switch tube Q11 is turned on, the output terminal of the second drive module 1083 outputs the first driving signal, such as a high-level signal. The fourteenth resistor R14 and the fifteenth resistor R15 play a current limiting role.

Optionally, based on various embodiments, in combination with FIGS. 10 and 11, the input logic module 1081 may include: a first AND gate U1. A first input terminal of the first AND gate U1 is connected to the calculation module 103 to be configured to receive the first control signal CTR_CHARGE_A as an input, a second input terminal of the first AND gate U1 is connected to the calculation module 103 to be configured to receive the second control signal CTR_DISCHARGE_A as an input, and an output terminal of the first AND gate U1 is connected to the first drive module 1082 and the second drive module 1083.

Specifically, when the first control signal CTR_CHARGE_A input into the first terminal and the second control signal CTR_DISCHARGE_A inputted into the second input terminal are of different logics, the first AND gate U1 outputs logic 0, and the first logic control signal is a low-level signal.

Optionally, based on various embodiments, in combination with FIGS. 10 and 11, the output logic module 1084 may include: a second AND gate U2, a fifth capacitor C5, and a sixteenth resistor R16. A first input terminal of the second AND gate U2 is connected to an output terminal of the second drive module 1083, and a second input terminal of the second AND gate U2 is connected to a first terminal of the fifth capacitor C5 and a first terminal of the sixteenth resistor R16. A second terminal of the fifth capacitor C5 is connected to ground. A second terminal of the sixteenth resistor is connected to an output terminal of the second AND gate U2, and the output terminal of the second AND gate U2 is configured to output the first voltage driving signal.

Specifically, a high electrical signal is input to the first input terminal of the second AND gate U2 of the output logic module 1084, and the second input terminal of the second AND gate U2 is grounded through the fifth capacitor C5. The fifth capacitor C5 is charged through the sixteenth resistor R16, so that a potential of the second input terminal of the second AND gate U2 is increased. The output terminal of the second AND gate U2 outputs the first voltage driving signal, for example, a high-level signal.

Optionally, based on various embodiments, in combination with FIGS. 10 and 11, the boost module 110 may include: a first-stage boost unit 111 and a second-stage boost unit 112. An input terminal of the first-stage boost unit 111 is connected to the output terminal of the drive module 108, an output terminal of the first-stage boost unit 111 and the output terminal of the switch module 109 are connected to a first node A, and the first-stage boost unit 111 is configured to perform a first-stage boost on a voltage of the first node A. The boost control circuit includes an output interface OUT, and the output interface OUT is connected to the first node A. The second-stage boost unit 112 is connected between the first-stage boost unit 111 and the first node A, and the second-stage boost unit 112 is configured to perform a second-stage boost on the voltage of the first node A. The output interface OUT is configured to output the second voltage signal after the second-stage boost.

Specifically, the first-stage boost unit 111 improves the capability of the first-stage boost unit 111 of storing electrical energy by changing a voltage difference between the input and output terminals of the first-stage boost unit 111, and performs the first-stage boost on the voltage of the first node A. The second-stage boost unit 112 is connected to the first-stage boost unit 111, and the second-stage boost unit 112 performs the second-stage boost on the voltage of the first node A, which increases the voltage of the first node A and can better ensure the stability of the second voltage signal output by the output interface OUT.

Optionally, based on various embodiments, in combination with FIGS. 10 and 11, the first-stage boost unit 111 includes: a first inverter U3, a sixth capacitor C6, and a seventeenth resistor R17. An input terminal of the first inverter U3 is connected to the output terminal of the drive module 108, an output terminal of the first inverter U3 is connected to a first terminal of the sixth capacitor C6, a second terminal of the sixth capacitor C6 is connected to a first terminal of the seventeenth resistor R17, and a second terminal of the seventeenth resistor R17 is connected to the output interface OUT. Optionally, the first inverter U3 is configured to invert the second voltage signal, the sixth capacitor C6 is configured to store electrical energy, and the seventeenth resistor R17 is configured to limit current.

Specifically, the first inverter U3 is configured to invert the first voltage driving signal and output the inverted signal. The sixth capacitor C6 is configured to store energy. The seventeenth resistor R17 is configured for current limiting protection. It can be set to have an energy storage voltage of the sixth capacitor C6 greater than a voltage of the second power supply. When the sixth capacitor C6 is fully charged, the switch module 109 is turned off, causing the sixth capacitor C6 to discharge, and an amplitude of the second voltage signal output by the output interface OUT is greater than an amplitude of the second power signal.

Optionally, based on various embodiments, in combination with FIGS. 10 and 11, the second-stage boost unit 112 may include: a second inverter U4, a seventh capacitor C7, and an eighteenth resistor R18. An input terminal of the second inverter U4 is connected to the output terminal of the first inverter U3, an output terminal of the second inverter U4 is connected to the first terminal of the seventh capacitor C7, a second terminal of the seventh capacitor C7 is connected to a first terminal of the eighteenth resistor R18, and a second terminal of the eighteenth resistor R18 is connected to the output interface OUT.

Optionally, the second inverter U4 is configured to invert an electrical signal output by the first inverter U3, the seventh capacitor C7 is configured to store electrical energy, and the eighteenth resistor R18 is configured to limit current.

Specifically, the second inverter U4 is configured to invert the inverted first voltage driving signal output through the first inverter U3. The seventh capacitor C7 is configured to store energy. The eighteenth resistor R18 is configured for current limiting protection. It can be set to have an energy storage voltage of the seventh capacitor C7 greater than the voltage of the first node A. When the seventh capacitor C7 is fully charged, the switch module 109 is turned off, causing the seventh capacitor C7 to discharge, increasing an amplitude of the second voltage signal output by the output interface OUT, and thus improving the capability of the second voltage signal output by the output interface OUT of the boost control circuit to drive the battery charging and discharging control MOS tube.

Optionally, based on various embodiments, in combination with FIGS. 10 and 11, the boost control circuit may further include: a surge control module 120 connected between the switch module 109 and the boost module 110, and the surge control module 120 is connected to the calculation module 103. The surge control module 120 is configured to be turned on in response to a third control signal of the calculation module 103 to reduce a surge of the boost control circuit.

Specifically, when the boost module 110 is being charged, the surge control module 120 plays a current limiting protection role. When the boost module 110 is boosted to have a voltage of the second power signal, the surge control module 120 is turned on in response to the third control signal, reducing self-consumed electricity of the surge control module 120, thereby protecting the boost control circuit and better avoiding the surge control module 120 from consuming the power.

Based on various embodiments, in combination with FIGS. 10 and 11, the surge control module 120 may include: a current-limiting resistor R19, a twelfth switch transistor Q12, a thirteenth switch transistor Q13, an eighth capacitor C8, a third voltage division network 51, and a fourth voltage division network 52. The current-limiting resistor R19 is connected between the switch module 109 and the boost module 110. A first electrode of the twelfth switch transistor Q12 is connected to the switch module 109 and to a first terminal of the third voltage division network 51, a second terminal of the twelfth switch transistor Q12 is connected to the boost module 110 and to a first electrode of the eighth capacitor C8, and a second terminal of the eighth capacitor C8 is grounded. A control terminal of the twelfth switch transistor Q12 is connected to a second terminal of the third voltage division network 51, and a third terminal of the third voltage division network 51 is connected to a first electrode of the thirteenth switch transistor Q13. A second electrode of the thirteenth switch transistor Q13 is grounded, and a control terminal of the thirteenth switch transistor Q13 is connected to a second terminal of the fourth voltage division network 52. A first terminal of the fourth voltage division network 52 is connected to the calculation module 103, and a third terminal of the fourth voltage division network 52 is grounded.

Specifically, when the boost module 110 is being charged, the current limiting resistor R19 plays a current limiting protection role. When a voltage of the boost module 110 is increased to the voltage of the second power signal, the thirteenth switch tube Q13 is turned on in response to the third control signal output by the calculation module 103, so that the control terminal of the twelfth switch tube Q12 is connected to a low-level signal, and the twelfth switch tube Q12 is turned on. The conducting twelfth switch tube Q12 bypasses the current limiting resistor R19, thereby reducing power loss of the current limiting resistor R19. The third voltage division network 51 plays a current limiting role, and the fourth voltage division network 52 plays a current limiting role. The eighth capacitor C8 plays an energy storage role. This may reduce self-consumed electricity of the surge control module 120, thereby protecting the boost control circuit and avoiding the surge control module 120 from consuming the electric energy.

Optionally, based on various embodiments, in combination with FIGS. 10 and 11, the switch module 109 includes: a switch tube Q29. A first electrode of the switch tube Q29 is configured to be connected to the second power terminal B+, a second electrode of the switch tube Q29 is connected to the input terminal of the surge control module 120, and a control terminal of the switch tube Q29 is connected to the output terminal of the first drive module 1082 of the drive module 108.

Optionally, an anti-reverse diode may be provided between the first node A and the output interface OUT.

Please refer to FIG. 12. FIG. 12 is a structural diagram of another electric vehicle provided by the present disclosure. Based on the embodiments provided by the present disclosure, as shown in FIG. 12, the present disclosure provides an electric vehicle, including the boost control circuit proposed in any embodiment.

Optionally, FIG. 12 illustrates, as an example, a charging switch tube M1 and a discharging switch tube M2 connected between the battery and the load. The boost control circuit proposed in any embodiment of the present disclosure includes a boost control module 170 connected between the calculation module 103, the battery, and the load. The calculation module 103 performs voltage boost according to a control signal received by its control terminal and outputs the second voltage signal. The charging control module 105 drives the charging switch tube M1 to turn on based on the second voltage signal according to the control signal of the calculation module 103, to enable an external power supply to charge the battery. The discharging control module 106 drives the discharging switch tube M2 to turn on based on the second voltage signal according to the control signal of the calculation module 103 to enable the battery to supply power to the load.

In related art, a circuit of the lithium battery BMS system is mainly controlled by a power switch tube. Considering the safety of the battery during charging and discharging, it is necessary to perform fault diagnosis on the power switch tube. The fault diagnosis on the power switch tube by detecting a voltage of the switch tube has low accuracy. After research, the applicant has found that the detection of the switch tube needs to consider factors such as a voltage drop across the switch tube, a magnitude of a pre-charging voltage and a change of the battery cell's own voltage. To this end, in some implementations, the present disclosure provides a switch tube detection circuit for a battery management system.

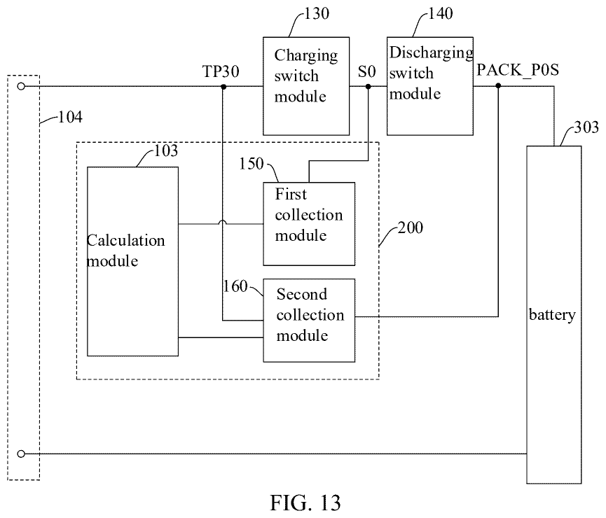

Please refer to FIG. 13. FIG. 13 is a schematic structural diagram of a connection between a switch tube detection circuit of a battery management system and the battery management system provided by the present disclosure. As shown in FIG. 13, the battery management system includes: a battery 303, a charging switch module 130, a battery switch module 140, and a charging and discharging interface 104. The charging and discharging interface 104 and the charging switch module 130 are connected to a first detection terminal TP30, the charging and discharging switch module 130 and the discharging switch module 140 are connected to the second detection terminal S0, and the discharging switch module 140 and the battery 303 are connected to the third detection terminal PACK_POS.

The switch tube detection circuit of the battery management system includes: a calculation module 103, a first collection module 150, and a second collection module 160. The calculation module 103 is configured to generate a first control signal and a second control signal. The first collection module 150 are connected to the calculation module 103 and to the second detection terminal S0, and the first collection module 150 is configured to collect a second voltage signal of the second detection terminal S0 according to the first control signal. The second collection module 160 is connected to the calculation module 103, the first detection terminal TP30, and the third detection terminal PACK_POS. The second collection module 160 is configured to collect a first voltage signal of the first detection terminal TP30 and collect a third voltage signal of the third detection terminal PACK_POS according to the second control signal. The calculation module 103 is configured to determine a fault state of the charging switch module 130 and of the discharging switch module 140 according to the first voltage signal, the second voltage signal, and the third voltage signal.

Specifically, the battery 303 provides energy to the battery management system. A working principle of the switch tube detection circuit of the battery management system is as follows. The calculation module 103 outputs the first control signal to the first collection module 150, and the first collection module 150 collects the voltage signal of the second detection terminal S0 according to the first control signal and transmits the voltage signal to the calculation module 103. The calculation module 103 outputs the second control signal to the second collection module 160, the second collection module 160 collects the voltage signals of the first detection terminal TP30 and of the third detection terminal PACK_POS according to the second control signal, and transmits the voltage signals to the calculation module 103. Since a voltage drop occurs across any one of the charging switch module 130 and the discharging switch module 140 when it is turned on, under normal circumstances, the voltage values of the third detection terminal PACK_POS, the second detection terminal S0, and the first detection terminal TP30 are decreasing in sequence. The calculation module 103 determines whether the charging switch module 130 and the discharging switch module 140 have a fault and a type of the fault based on differences between the voltage values of the first voltage signal, the second voltage signal, and the third voltage signal.

For example, the system is powered on, and the calculation module 103 outputs the first control signal and the second control signal. When the calculation module 103 controls both the charging switch module 130 and the discharging switch module 140 to turn off, if the voltage of the second detection terminal S0 is equal to the voltage of the third detection terminal PACK_POS, a short circuit failure occurs in the discharging switch module 140. When the calculation module 103 controls the charging switch module 130 to turn off and the discharging switch module 140 to turn on, if the voltage of the second detection terminal S0 is not equal to the voltage of the third detection terminal PACK_POS, an open circuit failure occurs in the discharging switch module 140. When the calculation module 103 controls the charging switch module 130 to turn off and the discharging switch module 140 to turn on, if the voltage of the first detection terminal TP30 is equal to the voltage of the second detection terminal S0, a short circuit failure occurs in the charging switch module 130. When the calculation module 103 controls the charging switch module 130 to turn on and the discharging switch module 140 to turn off, if the voltage of the first detection terminal TP30 is not equal to the voltage of the second detection terminal S0, an open circuit failure occurs in the charging switch module 130.

This technical solution provided by the present disclosure configures the first collection module 150 and the second collection module 160 to respectively collect the voltage signals at both terminals of each of the charging switch module 130 and the discharging switch module 140. Since any of the charging switch module 130 and the discharging switch module 140, when conducting, exhibits a voltage drop across its terminals, there is differences among the voltage values of the first voltage signal, the second voltage signal, and the third voltage signal. Whether the charging switch module 130 and the discharging switch module 140 have a fault and the type of the fault can be determined by the calculation module 103 based on the differences between the voltage values of the first voltage signal, the second voltage signal, and the third voltage signal. The technical solution provided by the present disclosure can detect a fault of the switch tube of the battery management system and improve the accuracy of fault diagnosis.

On the basis of various embodiments, optionally, the charging switch module 130 includes: N charging switch tubes, where N is a positive integer greater than or equal to 1. The discharging switch module 140 includes: N discharging switch tubes and N bypass resistors. An i^{th} charging switch tube is connected to an i^{th} discharging switch tube at an i^{th} node, wherein the second detection terminal S0 includes N nodes, where i is a positive integer ranging from 1 to N. An i^{th} bypass resistor is connected in parallel to and between first and second electrodes of the i^{th} discharging switch tube.

The first collection module 150 includes: N sampling units. Control terminals of the N sampling units are connected to a first enable terminal EN_1 of the calculation module 103, and an input terminal of an N^{th} sampling unit is connected to the N^{th} node. An output terminal of the N^{th} sampling unit is connected to an N^{th} input terminal of the calculation module 103.

Specifically, after the battery management system is powered on, the N bypass resistors participate in pre-charging of the battery management system, and a voltage of each node will rise. A rising voltage value and pre-charge time of the bypass resistor are related to a value of the bypass resistor and an RC time constant of a system parasitic capacitor. Since there is a voltage drop across the charging switch tube, the voltage of the first detection terminal TP30 decreases relative to the voltage of the corresponding node, and a decreased value is related to a magnitude of the voltage drop across the charging switch tube. Exemplary, when the power supply voltage is 12 voltages (V), after the battery management system is powered on, the N^{th} bypass resistor participates in the pre-charging of the battery management system, the voltage of the N^{th} node rises to about 11V in about 1 second, and the voltage of the first detection terminal TP30 is about 10.8V.

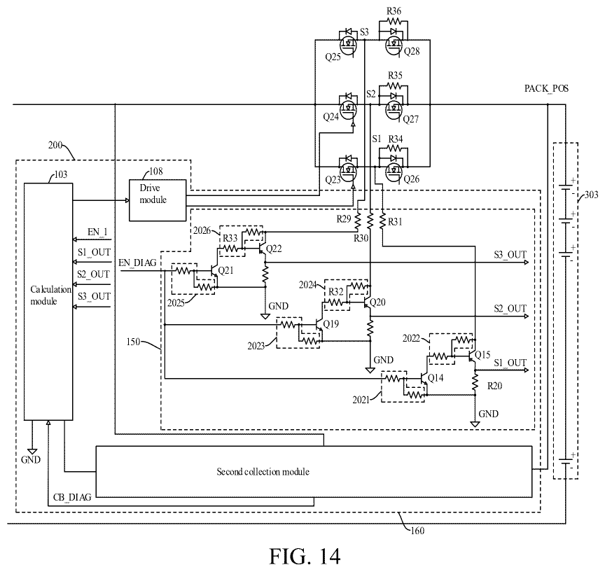

In some embodiments, as shown in FIG. 14, the battery management system further includes a drive module 108, and the calculation module 103 further includes a drive control terminal. An input terminal of the drive module 108 is connected to the drive control terminal. The drive module 108 includes 2N output terminals, and the 2N output terminals of the drive module 108 are connected to the N charging switch tubes and the N discharging switch tubes, respectively. The calculation module 103 outputs, from its drive control terminal, a control signal to the drive module 108, and uses the drive module 108 to control the conduction or shutdown of a corresponding charging switch tube and a corresponding discharging switch tube, so that the system can operate in a charging or discharging state.

In this embodiment, N charging switch tubes, N discharging switch tube, and N bypass resistors are configured, and further, N sampling units are configured to collect midpoint voltages and terminal voltages of the charging switch tubes and the discharging switch tubes, and a fault state of the switch tubes is diagnosed using the differences in the voltage signals. This arrangement is conducive to the flexibility of circuit design and improves the accuracy of fault diagnosis.

Based on various embodiments, the number of the charging switch tubes, the discharging switch tubes, and the sampling units can be designed according to actual needs, and is not limited here. Next, taking N=3 as an example, some possible specific structures and working principles of the battery management system will be described.

Please refer to FIG. 14. FIG. 14 is a schematic diagram of a circuit connection between the switch tube detection circuit of the battery management system and the battery management system provided by the present disclosure. As shown in FIG. 14, based on various embodiments, optionally, the sampling unit includes: a fourteenth switch tube Q14, a fifteenth switch tube Q15, a fifth voltage division network 2021, a sixth voltage division network 2022, and a twentieth resistor R20.

A control terminal of the fourteenth switch tube Q14 is connected to the first enable terminal EN_1 of the calculation module 103, first and second terminals of the fifth voltage division network 2021 are connected between the control terminal of the fourteenth switch tube Q14 and the first enable terminal EN_1 of the calculation module 103, and a third terminal of the fifth voltage divisionr network 2021 is connected to a second electrode of the fourteenth switch tube Q14 at a ground terminal GND.

A first electrode of the fourteenth switch tube Q14 is connected to a control terminal of the fifteenth switch tube Q15, a first electrode of the fifteenth switch tube Q15 is connected to the second detection terminal S0, a first terminal and a second terminal of the sixth voltage division network 2022 are connected between the control terminal of the fifteenth switch tube Q15 and the first electrode of the fourteenth switch tube Q14, a third terminal of the sixth voltage division network 2022 is connected to the first electrode of the fifteenth switch tube Q15, and a second electrode of the fifteenth switch tube Q15 is connected to the first terminal of the twentieth resistor R20 and the first input terminal of the calculation module 103. The second terminal of the twentieth resistor R20 is connected to ground.

Specifically, the calculation module 103 controls the first enable terminal EN_1 to be at a high level. After the fifth voltage division network 2021 performs the voltage division, the control terminal of the fourteenth switch tube Q14 is connected to the high-level signal to control the fourteenth switch tube Q14 to turn on. After the conduction voltage is divided by the sixth voltage division network 2022, the control terminal of the fifteenth switch tube Q15 receives the voltage signal of the first electrode of the fourteenth switch tube Q14 to control the fifteenth switch tube Q15 to turn on. The second electrode of the fifteenth switch tube Q15 is grounded through the twentieth resistor R20. The voltage signal of the second detection terminal S0 can be obtained by calculating the voltage difference between the first electrode of the fifteenth switch tube Q15 and the second electrode of the fifteenth switch tube Q15 and then is transmitted to the calculation 103 to perform the fault diagnosis.

Exemplary, when N=3, as shown in FIG. 14, the charging switch module 130 includes: a first charging switch tube Q23, a second charging switch tube Q24, and a third charging switch tube Q25. The discharging switch module 140 includes: a first bypass resistor R34, a second bypass resistor R35, a third bypass resistor R36, a first discharging switch tube Q26, a second discharging switch tube Q27, and a third discharging switch tube Q28. The second detection terminal S0 includes: a first node S1, a second node S2, and a third node S3. The voltage signals of the second detection terminal S0 includes: a first collection signal S1_OUT, a second collection signal S2_OUT, and a third collection signal S3_OUT. The sampling unit further includes: a nineteenth switching transistor Q19, a twentieth switching transistor Q20, a seventh voltage division network 2023, an eighth voltage division network 2024, a thirty-second resistor R32, a twenty-first switching transistor Q21, a twenty-second switching transistor Q22, a ninth voltage division network 2025, a tenth voltage division network 2026, and a thirty-third resistor R33.

In this embodiment, by configuring the fourteenth switch tube Q14, the fifteenth switch tube Q15, the fifth voltage division network 2021, the sixth voltage division network 2022, and the twentieth resistor R20 in the sampling unit, the collection and transmission of the voltage signal of the second detection terminal S0 are realized. Such configuration has a simple structure and is conducive to improving the accuracy of fault diagnosis.

Referring to FIG. 14, on the basis of various embodiments, optionally, the sampling unit further includes a current limiting resistor connected between the first electrode of the fifteenth switch tube Q15 and the second detection terminal S0.

Specifically, a resistance value of the current limiting resistor is designed according to actual requirements. The current limiting resistor can prevent the current flowing through the first electrode of the fifteenth switch tube Q15 and the second detection terminal S0 from being too large and damaging the switch tube. Exemplary, when N=3, the sampling unit includes a first current limiting resistor R29, a second current limiting resistor R30, and a third current limiting resistor R31.

In the present disclosure, by configuring the current limiting resistor, the circuit safety is improved by preventing excessive current from damaging the switch tube and the circuit.

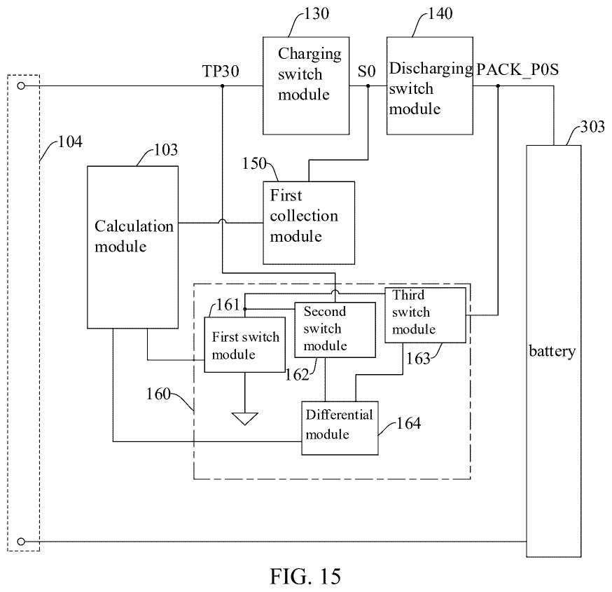

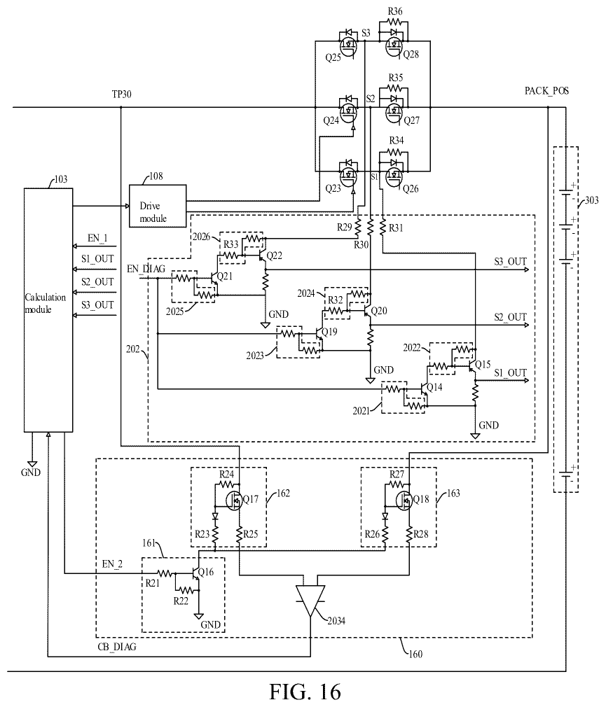

Please refer to FIG. 15. FIG. 15 is a schematic diagram of another circuit connection between the switch tube detection circuit of the battery management system and the battery management system provided by the present disclosure. As shown in FIG. 15, on the basis of various embodiments, the second collection module 160 optionally includes a first switch module 161, a second switch module 162, a third switch module 163, and a differential module 164.

A control terminal of the first switch module 161 is connected to a second enable terminal EN_2 of the calculation module 103, and a first terminal of the first switch module 161 is connected to a control terminal of the second switch module 162 and a control terminal of the third switch module 163. A second terminal of the first switch module 161 is grounded, and the first switch module 161 is configured to control the first switch module 161 and the second switch module 162 to be turned on according to the second control signal. A first terminal of the second switch module 162 is connected to the first detection terminal TP30, and a second terminal of the second switch module 162 is connected to an first input terminal of the differential module 164. The second switch module 162 is configured to output the collected first voltage signal to the differential module 164. A first terminal of the third switch module 163 is connected to the third detection terminal PACK_POS, and a second terminal of the third switch module 163 is connected to a second input terminal of the differential module 164. The third switch module 163 is configured to output the collected third voltage signal to the differential module 164. An output terminal of the differential module 164 is connected to the second input terminal of the calculation module 103, and the differential module 164 is configured to perform a differential calculation based on the received first voltage signal and third voltage signal, and output a differential signal CB DIAG to the calculation module 103.

Specifically, the calculation module 103 controls the second enable terminal EN_2 to be at a high level, and the control terminal of the first switch module 161 is connected to the high-level signal and controls the first switch module 161 to turn on. The control terminal of the second switch module 162 and the control terminal of the third switch module 163 receive a voltage signal of the first terminal of the first switch module 161 and then are turned on. Then, the voltage signal of the first detection terminal TP30 is transmitted through the second switch module 162 and is input into the differential module 164 from the second terminal of the second switch module 162. Then, the voltage signal of the third detection terminal PACK_POS is transmitted through the third switch module 163 and is input into the differential module 164 from the second terminal of the third switch module 163. The differential module 164 performs the differential calculation on the received first voltage signal and the received third voltage signal, and outputs the differential signal CB DIAG to the calculation module 103.

In this embodiment, by providing the first switch module 161, the second switch module 162, the third switch module 163, and the differential module 164 in the second collection module 160, the voltage signals of the first detection terminal TP30 and the third detection terminal PACK_POS are collected and transmitted. Such a configuration has a simple structure and is conducive to improving the accuracy of fault diagnosis.

Please refer to FIG. 16. FIG. 16 is a schematic diagram of still another circuit connection between the switch tube detection circuit of the battery management system and the battery management system provided by the present disclosure. As shown in FIG. 16, on the basis of various embodiments, optionally, the first switch module 161 includes: a sixteenth switch tube Q16, a twenty-first resistor R21, and a twenty-second resistor R22. A control terminal of the sixteenth switch tube Q16 is connected to a first terminal of the twenty-first resistor R21, and a second terminal of the twenty-first resistor R21 serves as the control terminal of the first switch module 161. The twenty-second resistor R22 is connected between the control terminal of the sixteenth switch tube Q16 and a second electrode of the sixteenth switch tube Q16, and the second electrode of the sixth switch tube Q16 is connected to the ground terminal GND. A first electrode of the sixteenth switch tube Q16 serves as the first terminal of the first switch module 161.

Specifically, the calculation module 103 controls the second enable terminal EN_2 to be at a high level, and the second terminal of the twenty-first resistor R21 receives the high-level signal, so that the high-level signal is input into the control terminal of the sixteenth switch tube Q16 through the first terminal of the twenty-first resistor R21, and at the same time, is input into the second electrode of the sixteenth switch tube Q16 through the twenty-second resistor R22, thereby turning on the sixteenth switch tube Q16. The first electrode of the sixteenth switch tube Q16 outputs a control signal to the second switch module 162 and the third switch module 163. The second electrode of the sixteenth switch tube Q16 is grounded.

In this embodiment, by providing the sixteenth switch tube Q16, the twenty-first resistor R21, and the twenty-second resistor R22 in the first switch module 161, the sixteenth switch tube Q16 is turned on. After receiving the second control signal from the calculation module 103, the sixteenth switch tube Q16 controls the second switch module 162 and the third switch module 163 to turn on, which is conducive to improving the accuracy of fault diagnosis.

Referring to FIG. 16, on the basis of various embodiments, optionally, the second switch module 162 includes: a seventeenth switch tube Q17, a twenty-third resistor R23, a twenty-fourth resistor R24, and a twenty-fifth resistor R25.

A control terminal of the seventeenth switch tube Q17 is connected to a first terminal of the twenty-third resistor R23 and a first terminal of the twenty-fourth resistor R24, and a second terminal of the twenty-third resistor R23 serves as the control terminal of the second switch module 162. A second terminal of the twenty-fourth resistor R24 is connected to a first electrode of the seventeenth switch tube Q17, as the first terminal of the second switch module 162. A second electrode of the seventeenth switch tube Q17 is connected to a first terminal of the twenty-fifth resistor R25. A second terminal of the twenty-fifth resistor R25 is used as a second terminal of the second switch module 162.

Specifically, the control signal output from the first electrode of the sixteenth switch tube Q16 is input into the control terminal of the seventeenth switch tube Q17 through the twenty-third resistor R23, and at the same time, is input into the first electrode of the seventeenth switch tube Q17 through the twenty-fourth resistor R24, so that the seventeenth switch tube Q17 is turned on. Then, by calculating a voltage difference between the first electrode of the seventeenth switch tube Q17 and a second electrode of the seventeenth switch tube Q17, the voltage signal of the first detection terminal TP30 can be obtained, and the voltage signal is output to the differential module 164 through the twenty-fifth resistor R25.

In this embodiment, by providing the seventeenth switch tube Q17, the twenty-third resistor R23, the twenty-fourth resistor R24, and the twenty-fifth resistor R25 in the second switch module 162, the seventeenth switch tube Q17 is turned on. After collecting the voltage signal of the first detection terminal TP30, the seventeenth switch tube Q17 transmits it to the differential module 164. The differential module 164 processes the voltage signal of the first detection terminal TP30 and then outputs it to the calculation module 103, which is conducive to improving the accuracy of fault diagnosis.

Referring to FIG. 16, on the basis of various embodiments, optionally, the third switch module 163 includes: an eighteenth switch tube Q18, a twenty-sixth resistor R26, a twenty-seventh resistor R27, and a twenty-eighth resistor R28.

A control terminal of the eighteenth switch tube Q18 is connected to a first terminal of the twenty-sixth resistor R26 and a first terminal of the twenty-seventh resistor R27, and a second terminal of the twenty-sixth resistor R26 serves as the control terminal of the third switch module 163. A second terminal of the twenty-seventh resistor R27 is connected to a first electrode of the eighteenth switch tube Q18, as the first terminal of the third switch module 163. A second electrode of the eighteenth switch tube Q18 is connected to a first terminal of the twenty-eighth resistor R28. A second terminal of the twenty-eighth resistor R28 is used as the second terminal of the third switch module 163.

Specifically, the control signal output from the first electrode of the sixteenth switch tube Q16 is input into the control terminal of the eighteenth switch tube Q18 through the twenty-sixth resistor R26, and at the same time, is input into the first electrode of the eighteenth switch tube Q18 through the twenty-seventh resistor R27, so that the eighteenth switch tube Q18 is turned on. Then, by calculating a voltage difference between the first electrode of the eighteenth switch tube Q18 and the second electrode of the eighteenth switch tube Q18, the voltage signal of the third detection terminal PACK_POS can be obtained, and the voltage signal is output to the differential module 164 through the twenty-eighth resistor R28.

In this embodiment, by providing the eighteenth switch tube Q18, the twenty-sixth resistor R26, the twenty-seventh resistor R27, and the twenty-eighth resistor R28 in the third switch module 163, the eighteenth switch tube Q18 is turned on. After collecting the voltage signal of the third detection terminal PACK_POS, the eighteenth switch tube Q18 transmits it to the differential module 164. The differential module 164 processes the voltage signal of the third detection terminal PACK_POS and outputs it to the calculation module 103, which is conducive to improving the accuracy of fault diagnosis.

On the basis of various embodiments, optionally, when the battery 303 is being charged, the calculation module 103 is configured to compare the first voltage signal with a first preset threshold, compare the second voltage signal with a second preset threshold, and compare the third voltage signal with a third preset threshold, to determine whether the charging switch module 130 and the discharging switch module 140 have a short circuit or an open circuit failure.

When the battery 303 is discharging, the calculation module 103 is configured to compare the first voltage signal with a fourth preset threshold, compare the second voltage signal with a fifth preset threshold, and compare the third voltage signal with a sixth preset threshold, to determine whether the charging switch module 130 and the discharging switch module 140 have a short circuit or an open circuit failure.

Exemplary, each preset threshold is determined based on the voltage signals corresponding to each detection terminal during a normal operation of the circuit. When the battery 303 is being charged, the first preset threshold value is set to Vb-1.2, the second preset threshold is Vb-1, and the third preset threshold is Vb. The system controls the charging switch module 130 to be turned on and the discharging switch module 140 to be turned off. If the first voltage signal and the second voltage signal are both Vb, the charging switch module 130 has a short circuit failure. If the first voltage signal is not equal to the second voltage signal and the second voltage signal is Vb-1, the charging switch module 130 has an open circuit failure. When the battery 303 is discharging, the fourth preset threshold is set to Vb-1.2, the fifth preset threshold is Vb-1, and the sixth preset threshold is Vb. The system controls the charging switch module 130 to be turned off and the discharging switch module 140 to be turned on. If the second voltage signal is Vb-1, the discharging switch module 140 is normal. If the second voltage signal is Vb, the discharging switch module 140 has a short circuit failure.

In this embodiment, by setting a preset threshold value corresponding to each voltage signal, using the calculation module 103 to compare the preset threshold value and corresponding voltage signal to diagnose the fault state of each switch module, the accuracy of fault diagnosis can be improved.

The present disclosure further provides a battery management system, which includes a switch tube detection circuit of the battery management system provided in any embodiment of the present disclosure.

The present disclosure further provides an electric vehicle that includes a switch tube detection circuit of the battery management system provided in any embodiment of the present disclosure, or a battery management system provided in any embodiment of the present disclosure.

In related art, when a battery management system (such as a 12V low-voltage lithium battery system) uses the ampere-hour integral method to measure SOC of a battery, it merely records the input charge and the output charge of the battery from the outside, without considering a change in an internal state of the battery management system. An electronic component in the battery management system also obtains power from the battery. Although a current of the electronic component is very small, long-term power accumulation will affect the SOC measurement accuracy of the battery management system.

The SOC detection circuit of the battery management system provided by some embodiments of the present disclosure collects the first current information flowing through the main circuit by connecting the first current collection module in series with the main circuit of the battery management system, and at the same time, collects the second current information flowing through the control circuit by connecting the second current collection module in series with the control circuit of the battery management system. That is, self-consumed electricity of the control circuit is taken into consideration. Further, the present disclosure calculates the SOC of the battery management system through the calculation module based on the first current information and the second current information, enabling the SOC detection circuit of the battery management system to calculate the SOC values of the self-consumed electricity of the control circuit and the main circuit of the battery management system. This reduces an error of the SOC calculation of the battery management system made by the SOC detection circuit of the battery management system, thereby improving the accuracy of the SOC calculation of the battery management system, and has a simple structure and saves cost.

The charging and discharging control circuit provided by some embodiments the present disclosure configures the calculation module to generate the first control signal and the second control signal in response to the operation instructions of the target user, and configures the charging control module to generate the charging control voltage in response to the first control signal, and configures the discharging control module to generate the discharging control voltage in response to the second control signal. The charging control voltage is configured to control the charging switch tube to turn on or turn off, and the discharging control voltage is configured to control the discharging switch tube to turn on or turn off. Compared with a circuit using a relay for charging and discharging control, it has a reduced volume.

The boost control circuit provided by some embodiments the present disclosure configures the calculation module to generate the first control signal and the second control signal in response to the operation instructions of the target user, and configures the drive module to generate the switch control signal and the first voltage driving signal in response to the first control signal and the second control signal. The switch module is connected to the second power terminal and the drive module, so that the switch module is turned on or off in response to the switch control signal. When the switch module is turned on, the boost module receives the second power signal and performs voltage boost based on the first voltage driving signal and the second power supply signal, and outputs a second voltage signal with an amplitude greater than that of the second power signal. In this way, the output interface of the boost control circuit can output the second voltage signal that meets the requirements of a driving voltage of an MOS tube for controlling the battery's charging and discharging.

A switch tube detection circuit of the battery management system provided by some embodiments the present disclosure configures the first collection module and the second collection module to respectively collect the voltage signals at both terminals of each of the charging switch module and the discharging switch module. Since a voltage drop occurs across any one of the charging switch module or the discharging switch module when it is turned on, there is differences between the first voltage signal, the second voltage signal, and the third voltage signal. The calculation module determines whether the charging switch module and the discharging switch module have a fault and a type of the fault based on the differences between the first voltage signal, the second voltage signal, and the third voltage signal, so as to realize a fault detection of the switch tubes of the battery management system and improve the accuracy of fault diagnosis.

What is claimed is:

1. A State of Charge (SOC) detection circuit of a battery management system, comprising:
a first current collection module, connected in series to a main circuit of the battery management system, and configured to collect first current information of the main circuit;
a second current collection module, connected in series to a control circuit of the battery management system and configured to collect second current information of the control circuit; and
a calculation module, connected to the first current collection module and to the second current collection module, respectively, and configured to calculate a SOC value of the battery management system based on the first current information and the second current information.

2. The SOC detection circuit of the battery management system according to claim 1, wherein the main circuit comprises:
a first interface, a charging and discharging control module, and a battery that are connected in series,
wherein the first interface is configured to be connected to a load or a charging power source, the first current collection module is connected between the first interface and the battery, and the first current collection module is configured to obtain a current flowing through the load in the main circuit;
wherein the first current collection module comprises:
a first sampling resistor,
wherein a first terminal of the first sampling resistor is connected to the first interface and a first sampling terminal of the calculation module, and a second terminal of the first sampling resistor is connected to a second electrode of the battery and a second sampling terminal of the calculation module.

3. The SOC detection circuit of the battery management system according to claim 1, wherein the control circuit is connected to the battery of the main circuit, and the battery is configured to supply power to the control circuit; the second current collection module is connected between a ground terminal of the control circuit and a second electrode of the battery, and is configured to collect a self-consumed current of the control circuit;
wherein the second current collection module comprises:
a second sampling resistor,
a first terminal of the second sampling resistor is connected to the second electrode of the battery and a third sampling terminal of the calculation module, and a second terminal of the second sampling resistor is connected to a fourth sampling terminal of the calculation module and the ground terminal.

4. The SOC detection circuit of the battery management system according to claim 1, wherein the calculation module comprises:
an analog-to-digital conversion unit, connected to the first current collection module and to the second current collection module, respectively, and configured to convert the first current information and the second current information into digital signals; and
a signal processing unit, connected to the analog-to-digital conversion unit and configured to calculate the SOC value of the battery management system based on the digital signals converted from the first current information and the second current information.

5. A charging and discharging control circuit, comprising:
a calculation module, configured to generate a first control signal and a second control signal in response to operation instructions from a target user;
a charging control module, connected to the calculation module and configured to generate a charging control voltage in response to the first control signal; and
a discharging control module, connected to the calculation module and configured to generate a discharging control voltage in response to the second control signal;
wherein the charging control voltage is configured to control a charging switch tube to turn on or turn off, and the discharging control voltage is configured to control a discharging switch tube to turn on or turn off.

6. The charging and discharging control circuit according to claim 5, wherein the charging control module comprises:
a first follower unit, connected to the calculation module, and configured to receive the first control signal and output the first control signal;
a first driving unit, connected to the first follower unit, and configured to turn on according to the first control signal and output a first power signal;
a first switch unit, connected to the first driving unit, and configured to turn on according to the first power signal;
a first output unit, connected to the first switch unit, and configured to output the charging control voltage.

7. The charging and discharging control circuit according to claim 6, wherein the first driving unit comprises:
a first switch tube, a second switch tube, a first resistor, a second resistor, a third resistor, and a fourth resistor;
wherein a first terminal of the first resistor is connected to an output terminal of the first follower unit, a second terminal of the first resistor is connected to a control terminal of the first switch tube, a first electrode of the first switch tube is connected to a control terminal of the second switch tube, and a second electrode of the first switch tube is grounded; a first electrode of the second switch tube is configured to be connected to a first power input terminal, and a second electrode of the second switch tube is connected to a control terminal of the first switch unit;
a second resistor is connected between the control terminal and the second electrode of the first switch tube, the third resistor is connected between the first electrode of the first switch tube and the control terminal of the second switch tube, and the fourth resistor is connected between the control terminal and the first electrode of the second switch tube.

8. The charging and discharging control circuit according to claim 6, wherein the first switch unit comprises:
a third switch tube and a fifth resistor;
wherein a control terminal of the third switch tube is connected to an output terminal of the first driving unit, a first electrode of the third switch tube is connected to a first terminal of the first output unit, and a second electrode of the third switch tube is grounded; and the fifth resistor is connected between the control terminal and the second electrode of the third switch tube);
wherein the first output unit comprises:
a first voltage division network, wherein a first terminal of the first voltage division network is connected to the first electrode of the third switch tube, a second terminal of the first voltage division network is configured to be connected to a second power input terminal, and a third terminal of the first voltage division network is configured to be connected to the control terminal of the charging switch tube.

9. The charging and discharging control circuit according to claim 5, wherein the discharging control module comprises:
a second follower unit, connected to the calculation module, and configured to receive the second control signal and output the second control signal;
a second driving unit, connected to the second follower unit, and configured to turn on according to the second control signal and output the first power signal;
a second switch unit, connected to the second driving unit, and configured to turn on according to the first power signal; and
a second output unit, connected to the second switch unit, and configured to output the discharging control voltage.

10. The charging and discharging control circuit according to claim 9, wherein the second driving unit comprises:
a fourth switch tube, a fifth switch tube, a sixth resistor, a seventh resistor, an eighth resistor, and a ninth resistor,
wherein a first terminal of the sixth resistor is connected to an output terminal of the second follower unit, a second terminal of the sixth resistor is connected to a control terminal of the fourth switch tube, a first electrode of the fourth switch tube is connected to a control terminal of the fifth switch tube, and a second electrode of the fourth switch tube is grounded; a first electrode of the fifth switch tube is configured to be connected to the first power input terminal, and a second electrode of the fifth switch tube is connected to a control terminal of the second switch unit;
a seventh resistor is connected between a control terminal and a second electrode of the fourth switch tube, the eighth resistor is connected between the first electrode of the fourth switch tube and the control terminal of the fifth switch tube; and the ninth resistor is connected between the control terminal and the first electrode of the fifth switch tube.

11. The charging and discharging control circuit according to claim 9, wherein the second switch unit comprises:
a sixth switch tube and a tenth resistor,
wherein a control terminal of the sixth switch tube is connected to an output terminal of the second driving unit, a first electrode of the sixth switch tube is connected to a first terminal of the second output unit, and a second electrode of the sixth switch tube is grounded; and the tenth resistor is connected between the control terminal and the second electrode of the sixth switch tube;
wherein the second output unit comprises:
a second voltage division network, wherein a first terminal of the second voltage division network is connected to the first electrode of the sixth switch tube, a second terminal of the second voltage division network is configured to connect to the second power input terminal, and a third terminal of the second voltage division network is configured to be connected to a control terminal of the discharging switch tube.

12. The charging and discharging control circuit according to claim 5, further comprising:
an initialization module,
wherein an input terminal of the initialization module is connected to the first power input terminal, and an output terminal of the initialization module is connected to the charging control module and the discharging control module; and
the initialization module is configured to initialize the charging control module and the discharging control module during an initial stage, control the charging switch tube to turn off, and control the discharging switch tube to turn off;
wherein the initialization module comprises:
a first capacitor, an eleventh resistor, and a twelfth resistor,
wherein a first terminal of the first capacitor is connected to the first power input terminal, a second terminal of the first capacitor is connected to a first terminal of the eleventh resistor and a first terminal of the twelfth resistor, a second terminal of the eleventh resistor is grounded, and a second terminal of the twelfth resistor is connected to a reset terminal of the first follower unit of the charging control module and a reset terminal of the second follower unit of the discharging control module.

13. The charging and discharging control circuit according to claim 5, further comprising a boost control circuit, comprising:
a drive module, connected to the calculation module and a first power terminal, and configured to generate a switch control signal and a first voltage driving signal in response to the first control signal and the second control signal;
a switch module, connected to a second power terminal and the drive module, and configured to turn on or turn off in response to the switch control signal; and
a boost module, connected to the switch module and the drive module, and configured to receive a second power signal from the second power terminal when the switch module is turned on, and performs voltage boost according to the second power signal and the first voltage driving signal to output a second voltage signal;
wherein an amplitude of the second voltage signal is greater than an amplitude of the second power signal.

14. The charging and discharging control circuit according to claim 13, wherein the boost control circuit comprises at least one of the following structures:
the drive module comprising:
an input logic module, connected to the calculation module, and configured to generate a first logic control signal based on the first control signal and the second control signal,
a first drive module, connected to the input logic module and the switch module, and configured to conduct according to the first logic control signal and output the switch control signal to the switch module,
a second drive module, connected to the input logic module and the first power terminal, and configured to output a first driving signal based on the first logic control signal and the first power signal output from the first power terminal, and
an output logic module, connected to the second drive module, and configured to generate the first voltage driving signal based on the first driving signal; or
the first drive module comprising:
a seventh switch tube, an eighth switch tube, and a thirteenth resistor),
wherein a control terminal of the seventh switch tube is connected to an output terminal of the input logic module, a first electrode of the seventh switch tube is connected to a control terminal of the eighth switch tube and a first terminal of the thirteenth resistor, a second terminal of the thirteenth resistor is configured to be connected to the first power terminal, a first electrode of the eighth switch tube is connected to a control terminal of the switch module, and a second electrode of the seventh switch tube and a second electrode of the eighth switch tube are grounded; or
the second drive module comprising:
a ninth switch tube, a tenth switch tube, an eleventh switch tube, a fourteenth resistor, and a fifteenth resistor
wherein a control terminal of the ninth switch tube is connected to an output terminal of the input logic module, a first electrode of the ninth switch tube is connected to a control terminal of the tenth switch tube and a first terminal of the fourteenth resistor, a second terminal of the fourteenth resistor is connected to the first power terminal, a first electrode of the tenth switch tube is connected to a control terminal of the eleventh switch tube and a first terminal of the fifteenth resistor, a second terminal of the fifteenth resistor is connected to a first electrode of the eleventh switch tube and the first power terminal; a second electrode of the ninth switch tube and a second electrode of the tenth switch tube are grounded, and a second electrode of the eleventh switch tube is connected as an output terminal of the second drive module to the output logic module; or
the input logic module comprising:
a first AND gate,
wherein a first input terminal of the first AND gate is connected to the calculation module to receive the first control signal, a second input terminal of the first AND gate is connected to the calculation module to receive the second control signal, and an output terminal of the first AND gate is connected to the first drive module and the second drive module; or
the output logic module comprising:
a second AND gate, a fifth capacitor, and a sixteenth resistor,
wherein a first input terminal of the second AND gate is connected to the output terminal of the second drive module, a second input terminal of the second AND gate is connected to a first terminal of the fifth capacitor and a first terminal of the sixteenth resistor, a second terminal of the fifth capacitor is grounded, a second terminal of the sixteenth resistor is connected to an output terminal of the second AND gate, and the output terminal of the second AND gate is configured to output the first voltage driving signal.

15. The charging and discharging control circuit according to claim 13, wherein the boost module comprises:
a first-stage boost unit, wherein an input terminal of the first-stage boost unit is connected to an output terminal of the drive module, an output terminal of the first-stage boost unit is connected to an output terminal of the switch module at a first node, and the first-stage boost unit is configured to perform a first-stage boost on a voltage of the first node, wherein the first node is connected to an output interface of the boost control circuit;
a second-stage boost unit, connected between the first-stage boost unit and the first node, and configured to perform a second-stage boost on the voltage of the first node; and
the output interface, configured to output the second voltage signal after the second-stage boost;
wherein the first-stage boost unit comprises:
a first inverter, a sixth capacitor, and a seventeenth resistor,
wherein an input terminal of the first inverter is connected to the output terminal of the drive module, an output terminal of the first inverter is connected to a first terminal of the sixth capacitor, a second terminal of the sixth capacitor is connected to a first terminal of the seventeenth resistor, and a second terminal of the seventeenth resistor is connected to the output interface; and
wherein the second-stage boost unit comprises:
a second inverter, a seventh capacitor, and an eighteenth resistor,
wherein an input terminal of the second inverter is connected to the output terminal of the first inverter, an output terminal of the second inverter is connected to a first terminal of the seventh capacitor, a second terminal of the seventh capacitor is connected to a first terminal of the eighteenth resistor, and a second terminal of the eighteenth resistor is connected to the output interface.

16. The charging and discharging control circuit according to claim 13, further comprising:
a surge control module,
wherein the surge control module is connected between the switch module and the boost module, and is connected to the calculation module, and
the surge control module is configured to conduct in response to a third control signal from the calculation module to reduce a surge of the boost control circuit;
wherein the surge control module comprises:
a current limiting resistor, a twelfth switch tube, a thirteenth switch tube, an eighth capacitor, a third voltage division network, and a fourth voltage division network,
wherein the current limiting resistor is connected between the switch module and the boost module,
a first electrode of the twelfth switch tube is connected to the switch module and a first terminal of the third voltage division network, a second electrode of the twelfth switch tube is connected to the boost module and a first terminal of the eighth capacitor, a second terminal of the eighth capacitor is grounded;
a control terminal of the twelfth switch tube is connected to a second terminal of the third voltage division network, a third terminal of the third voltage division network is connected to a first electrode of the thirteenth switch tube, and a second electrode of the thirteenth switch tube is grounded;
a control terminal of the thirteenth switch tube is connected to a second terminal of the fourth voltage division network, a first terminal of the fourth voltage division network is connected to the calculation module, and a third terminal of the fourth voltage division network is grounded.

17. A switch tube detection circuit of a battery management system, wherein the battery management system comprises:
a battery, a charge switch module, a discharging switch module, and a charging and discharging interface;
wherein the charging and discharging interface is connected to the charging switch module at a first detection terminal, the charging switch module is connected to the discharging switch module at a second detection terminal, and the discharging switch module is connected to the battery at a third detection terminal;
the switch tube detection circuit of the battery management system comprising:
a calculation module, configured to generate a first control signal and a second control signal;
a first collection module, connected to the calculation module and the second detection terminal, and configured to collect a second voltage signal of the second detection terminal according to the first control signal;
a second collection module, connected to the calculation module, the first detection terminal, and the third detection terminal, and configured to collect a first voltage signal of the first detection terminal and a third voltage signal of the third detection terminal according to the second control signal;
wherein the calculation module is further configured to determine a fault state of the charging switch module and a fault state of the discharging switch module based on the first voltage signal, the second voltage signal, and the third voltage signal.

18. The switch tube detection circuit of the battery management system according to claim 17, wherein:
the charging switch module comprises N charging switch tubes, where Nis a positive integer greater than or equal to 1, and
the discharging switch module comprises N discharging switch tubes and N bypass resistors;
wherein the second detection terminal comprises N nodes, an N^{th} charging switch tube of the N charging switch tubes is connected to an N^{th} discharging switch tube of the N discharging switch tubes at an N^{th} node of the N nodes, and an N^{th} bypass resistor of the N bypass resistors is connected in parallel between a first electrode and a second electrode of the N^{th} discharging switch tube; and
the first collection module comprises N sampling units, control terminals of the N sampling units are connected to a first enable terminal of the calculation module, an input terminal of an N^{th} sampling unit of the N sampling units is connected to the N^{th} node, and an output terminal of the N^{th} sampling unit is connected to an N^{th} input terminal of the calculation module.

19. The switch tube detection circuit of the battery management system according to claim 18, wherein one of the sampling units comprises:
a fourteenth switch tube, a fifteenth switch tube, a fifth voltage division network, a sixth voltage division network, and a twentieth resistor;
wherein a control terminal of the fourteenth switch tube is connected to the first enable terminal of the calculation module, a first terminal of the fifth voltage division network and the second terminal of the fifth voltage division network are connected between a control terminal of the fourteenth switch tube and the first enable terminal of the calculation module, a third terminal of the fifth voltage division network and a second electrode of the fourteenth switch tube are connected to a ground terminal;
a first electrode of the fourteenth switch tube is connected to a control terminal of the fifteenth switch tube, a first electrode of the fifteenth switch tube is connected to the second detection terminal, a first terminal and the second terminal of the sixth voltage division network is connected between the control terminal of the fifteenth switch tube and the first electrode of the fourteenth switch tube, a third terminal of the sixth voltage division network is connected to the first electrode of the fifteenth switch tube, a second electrode of the fifteenth switch tube is connected to a first terminal of the twentieth resistor and a first input terminal of the calculation module, and a second terminal of the twentieth resistor is grounded;
wherein the sampling unit further comprises:
a current limiting resistor,
wherein the current limiting resistor is connected between the first electrode of the fifteenth switch tube and the second detection terminal.

20. The switch tube detection circuit of the battery management system according to claim 17, wherein the second collection module comprises:
a first switch module, a second switch module, a third switch module, and a differential module,
wherein a control terminal of the first switch module is connected to a second enable terminal of the calculation module, a first terminal of the first switch module is connected to a control terminal of the second switch module and a control terminal of the third switch module; a second terminal of the first switch module is grounded, and the first switch module is configured to control the second switch module and the third switch module to turn on according to the second control signal;
a first terminal of the second switch module is connected to the first detection terminal, a second terminal of the second switch module is connected to a first input terminal of the differential module; the second switch module is configured to output the collected first voltage signal to the differential module;
a first terminal of the third switch module is connected to the third detection terminal, a second terminal of the third switch module is connected to a second input terminal of the differential module; the third switch module is configured to output the collected third voltage signal to the differential module;
an output terminal of the differential module is connected to the second input terminal of the calculation module, and the differential module is configured to perform differential calculation based on the received first voltage signal and the received third voltage signal, and output a differential signal to the calculation module.

21. The switch tube detection circuit of the battery management system according to claim 20, wherein the first switch module comprises:
a sixteenth switch tube, a twenty-first resistor, and a twenty-second resistor,
wherein a control terminal of the sixteenth switch tube is connected to a first terminal of the twenty-first resistor, and a second terminal of the twenty-first resistor serves as the control terminal of the first switch module;
the twenty-second resistor is connected between the control terminal of the sixteenth switch tube and a second electrode of the sixteenth switch tube, and the second electrode of the sixteenth switch tube is connected to the ground terminal;
a first electrode of the sixteenth switch tube serves as the first terminal of the first switch module.

22. The switch tube detection circuit of the battery management system according to claim 21, comprising at least one of the following structures:
the second switch module comprising:
a seventeenth switch tube, a twenty-third resistor, a twenty-fourth resistor, and a twenty-fifth resistor,
wherein a control terminal of the seventeenth switch tube is connected to a first terminal of the twenty-third resistor and a first terminal of the twenty-fourth resistor, a second terminal of the twenty-third resistor serves as the control terminal of the second switch module; a second terminal of the twenty-fourth resistor is connected to a first electrode of the seventeenth switch tube, serving as the first terminal of the second switch module, a second electrode of the seventeenth switch tube is connected to a first terminal of the twenty-fifth resistor, and a second terminal of the twenty-fifth resistor serves as the second terminal of the second switch module; or
the third switch module comprising:
an eighteenth switch tube, a twenty-sixth resistor, a twenty-seventh resistor, and a twenty-eighth resistor,
wherein a control terminal of the eighteenth switch tube is connected to a first terminal of the twenty-sixth resistor and a first terminal of the twenty-seventh resistor, a second terminal of the twenty-sixth resistor serves as the control terminal of the third switch module; a second terminal of the twenty-seventh resistor is connected to a first electrode of the eighteenth switch tube, serving as the first terminal of the third switch module, a second electrode of the eighteenth switch tube is connected to a first terminal of the twenty-eighth resistor, and a second terminal of the twenty-eighth resistor serves as the second terminal of the third switch module.

23. The switch tube detection circuit of the battery management system according to claim 17, wherein:
when the battery is being charged, the calculation module is configured to compare the first voltage signal with a first preset threshold, the second voltage signal with a second preset threshold, and the third voltage signal with a third preset threshold, to determine whether the charging switch module and the discharging switch module have a short-circuit fault or an open-circuit fault;
when the battery is discharging, the calculation module is configured to compare the first voltage signal with a fourth preset threshold, the second voltage signal with a fifth preset threshold, and the third voltage signal with a sixth preset threshold, to determine whether the charge switch module and the discharging switch module have a short-circuit fault or an open-circuit fault.
